(19) United States
(12) Patent Application Publication
(10) Pub. No.: US 2025/0228101 A1
(43) Pub. Date: Jul. 10, 2025

(54) DISPLAY DEVICE, OPTICAL DEVICE, AND METHOD OF MANUFACTURING THE DISPLAY DEVICE

(71) Applicant: Samsung Display Co., LTD., Yongin-si (KR)

(72) Inventor: Hyun Eok SHIN, Yongin-si (KR)

(21) Appl. No.: 18/916,386

(22) Filed: Oct. 15, 2024

(30) Foreign Application Priority Data
Jan. 8, 2024 (KR) 10-2024-0002732

(51) Int. Cl. H10K 59/80; H10K 59/12; H10K 59/122; H10K 102/00

(52) U.S. Cl. CPC H10K 59/80515; H10K 59/1201; H10K 59/122; H10K 59/80521; H10K 2102/351

(57) ABSTRACT

A display device, more particularly, to a display device capable of manufacturing fine patterns while having high reflectivity, an optical device, and a method of manufacturing the display device is provided. A display device includes: a substrate; a first electrode on the substrate; a light emitting layer on the first electrode; and a second electrode on the light emitting layer, the first electrode including: a first pattern layer including aluminum; a second pattern layer on the first pattern layer and including a transparent conductive material; a third pattern layer on the second pattern layer and including silver; and a fourth pattern layer on the third pattern layer and including a transparent conductive material.

### CROSS-REFERENCE TO RELATED APPLICATION

The present application claims priority to and the benefit of Korean Patent Application No. 10-2024-0002732, filed on Jan. 8, 2024, in the Korean Intellectual Property Office, the entire disclosure of which is incorporated by reference herein.

### BACKGROUND

### 1. Field

The present disclosure relates to a display device, more particularly, to a display device capable of manufacturing fine patterns while having high reflectivity, an optical device, and a method of manufacturing the display device.

### 2. Description of the Related Art

A head mounted display (HMD) is an image display device that is worn on a user's head in the form of glasses or a helmet and forms a focus at a distance close to user's eyes in front of the user's eyes. The head mounted display may implement virtual reality (VR) or augmented reality (AR).

The head mounted display magnifies and displays an image displayed by a small display device using a plurality of lenses. Therefore, a display device applied to the head mounted display needs to provide a high-resolution image, for example, an image having a resolution of 3000 pixels per inch (PPI) or more. To this end, an organic light emitting diode on silicon (OLEDoS), which is a small organic light emitting display device having a high resolution, has been used as the display device applied to the head mounted display. The OLEDoS is a device that displays an image by disposing organic light emitting diodes (OLEDs) on a semiconductor wafer substrate on which complementary metal oxide semiconductors (CMOSs) are disposed.

### SUMMARY

Aspects and features of embodiments of the present disclosure provide a display device capable of manufacturing fine patterns while having high reflectivity, an optical device, and a method of manufacturing the display device.

According to one or more embodiments of the present disclosure, a display device including: a substrate; a first electrode on the substrate; a light emitting layer on the first electrode; and a second electrode on the light emitting layer, wherein the first electrode includes: a first pattern layer containing aluminum; a second pattern layer on the first pattern layer and containing a transparent conductive material; a third pattern layer on the second pattern layer and containing silver; and a fourth pattern layer on the third pattern layer and containing transparent conductive material.

In one or more embodiments, the first pattern layer has a greater thickness than the thickness of the third pattern layer.

In one or more embodiments, the thickness of the first pattern layer is four times the thickness of the third pattern layer.

In one or more embodiments, the first pattern layer has a thickness in a range of 700 Å to 1000 Å.

In one or more embodiments, the third pattern layer has a thickness in a range 200 Å to 300 Å.

In one or more embodiments, the second pattern layer has a thickness equal to or less than 100 Å.

In one or more embodiments, the fourth pattern layer has a thickness equal to or less than 100 Å.

In one or more embodiments, in a plan view, the first pattern layer has a greater area than the third pattern layer.

In one or more embodiments, in a plan view, the first pattern layer has a greater area than the second pattern layer or the fourth pattern layer.

In one or more embodiments, the third pattern layer is surrounded by the second pattern layer and the fourth pattern layer.

In one or more embodiments, further including a pixel defining film on the first electrode.

In one or more embodiments, the pixel defining film is on the second pattern layer and overlaps an edge area of the first pattern layer.

In one or more embodiments, the pixel defining film is on the second pattern layer and the fourth pattern layer and overlaps the edge area of the first pattern layer.

In one or more embodiments, the transparent conductive material includes ITO.

According to one or more embodiments of the present disclosure, an optical device including: a display device; and an optical path conversion member on the display device, wherein the display device includes: a substrate; a first electrode on the substrate; a light emitting layer on the first electrode; and a second electrode on the light emitting layer, wherein the first electrode includes: a first pattern layer containing aluminum; a second pattern layer on the first pattern layer and containing a transparent conductive material; a third pattern layer on the second pattern layer and containing silver; and a fourth pattern layer on the third pattern layer and containing a transparent conductive material.

In one or more embodiments, the first pattern layer has a greater thickness than the third pattern layer.

In one or more embodiments, in a plan view, the first pattern layer has a greater area than the third pattern layer.

In one or more embodiments, in a plan view, the first pattern layer has a greater area than the second pattern layer or the fourth pattern layer.

According to one or more embodiments of the present disclosure, a method of manufacturing a display device, the method including forming a first electrode on a substrate, wherein forming the first electrode includes: sequentially forming a first material layer containing aluminum, a second material layer containing a transparent conductive material, a third material layer containing silver, and a fourth material layer containing a transparent conductive material; forming a photoresist pattern on the fourth material layer; forming a fourth pattern layer by wet etching the fourth material layer using the photoresist pattern as a mask; forming a third pattern layer by wet etching the third material layer using the photoresist pattern as a mask; and forming each of the second pattern layer and the first pattern layer by respectively dry etching the second material layer and the first material layer using the photoresist pattern as a mask.

In one or more embodiments the method further including: forming a pixel defining film on a first electrode including the first pattern layer, the second pattern layer, the third pattern layer, and the fourth pattern layer; forming a light emitting layer on the first electrode and the pixel defining film; and forming a second electrode on the light emitting layer.

According to one or more embodiments of the present disclosure, a first electrode may be manufactured in a fine pattern while having high reflectivity.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail embodiments thereof with reference to the attached drawings, in which:

FIG. 1 is an exploded perspective view illustrating a display device according to one or more embodiments;

FIG. 2 is a block diagram illustrating the display device according to one or more embodiments;

FIG. 3 is an equivalent circuit diagram of a first pixel according to one or more embodiments;

FIG. 4 is a layout diagram illustrating an example of a display panel according to one or more embodiments;

FIGS. 5 and 6 are layout diagrams illustrating embodiments of a display area of FIG. 4;

FIG. 7 is a cross-sectional view illustrating an example of the display panel taken along the line I1-I1′ of FIG. 5;

FIG. 8 is a plan view of a display device according to one or more embodiments;

FIG. 9 is a cross-sectional view taken along the line I-I′ of FIG. 8;

FIG. 10 is a cross-sectional view of a display device according to one or more embodiments;

FIG. 11 is a plan view of a display device according to one or more embodiments;

FIG. 12 is a cross-sectional view taken along the line II-II′ of FIG. 11;

FIG. 13 is a cross-sectional view of a display device according to one or more embodiments;

FIGS. 14-20 are cross-sectional views for explaining processes of a method of manufacturing a display device according to one or more embodiments;

FIG. 21 is a perspective view illustrating a head mounted display device according to one or more embodiments;

FIG. 22 is an exploded perspective view illustrating an example of the head mounted display device of FIG. 21; and

FIG. 23 is a perspective view illustrating a head mounted display device according to one or more embodiments.

### DETAILED DESCRIPTION

Aspects and features of embodiments of the present disclosure and methods to achieve them will become apparent from the descriptions of embodiments hereinbelow with reference to the accompanying drawings. However, the present disclosure is not limited to embodiments disclosed herein but may be implemented in various different ways. The embodiments are provided for making the present disclosure thorough and for fully conveying the scope of the present disclosure to those skilled in the art. It is to be noted that the scope of the present disclosure may be defined by the claims and their equivalents.

As used herein, a phrase “an element A on an element B” refers to that the element A may be disposed directly on the element B and/or the element A may be disposed indirectly on the element B via another element C. Like reference numerals denote like elements throughout the present disclosure. The figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the present disclosure.

Features of various embodiments of the present disclosure may be combined partially or totally. As will be clearly appreciated by those skilled in the art, technically various interactions and operations are possible. Various embodiments can be practiced individually or in combination.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure will be described with reference to the accompanying drawings.

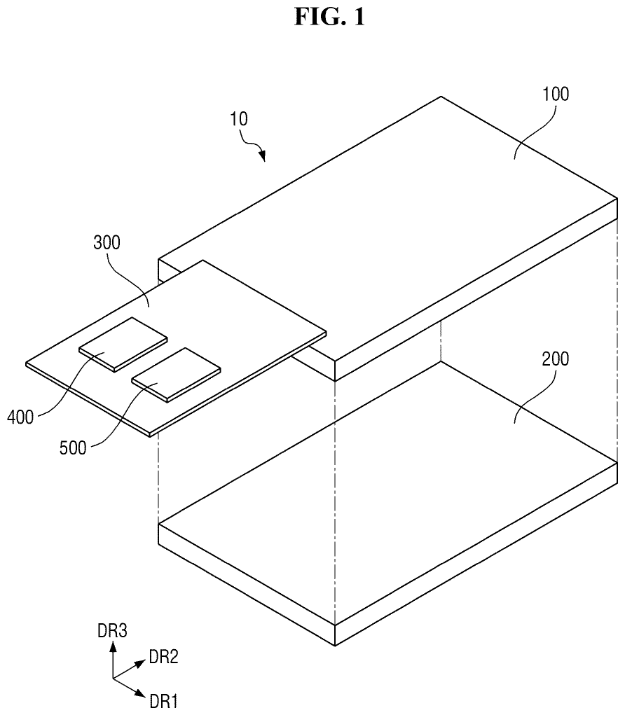

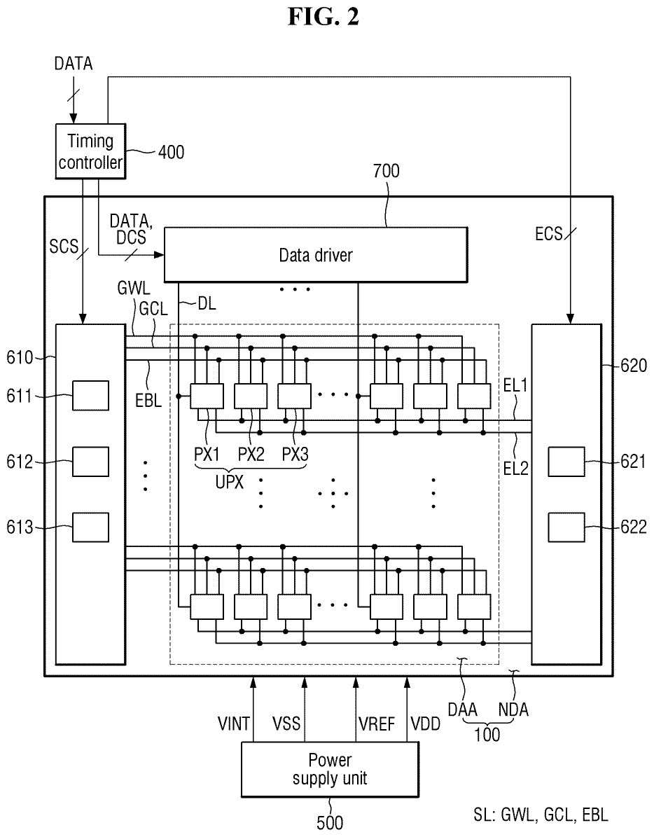

FIG. 1 is an exploded perspective view illustrating a display device according to one or more embodiments. FIG. 2 is a block diagram illustrating the display device according to one or more embodiments.

Referring to FIGS. 1 and 2, a display device 10 according to one or more embodiments is a device that displays a moving image and/or a still image. The display device 10 according to one or more embodiments may be applied to portable electronic devices such as mobile phones, smartphones, tablet personal computers (PCs), mobile communication terminals, electronic notebooks, electronic books, portable multimedia players (PMPs), navigation devices, and/or ultra mobile PCs (UMPCs). For example, the display device 10 according one or more embodiments may be applied as a display part (e.g., a display unit) of televisions, laptop computers, monitors, billboards, and/or the Internet of Things (IOTs). Alternatively, the display device 10 according to one or more embodiments may be applied to smart watches, watch phones, and/or head mounted displays (HMDs) for implementing virtual reality and/or augmented reality.

The display device 10 according to one or more embodiments includes a display panel 100, a heat dissipation layer 200, a circuit board 300, a timing controller 400, and a power supply unit 500.

The display panel 100 may have a shape similar to a rectangular shape in a plan view. For example, the display panel 100 may have a shape similar to a rectangular shape, in a plan view, having short sides in a first direction DR1 and long sides in a second direction DR2 crossing the first direction DR1. In the display panel 100, a corner where the short side in the first direction DR1 and the long side in the second direction DR2 meet may be rounded with a suitable curvature (e.g., a predetermined curvature) or right-angled. The shape of the display panel 100 in a plan view is not limited to the rectangular shape, and may be a shape similar to other polygonal shapes, a circular shape, and/or an elliptical shape. A shape of the display device 10 in a plan view may follow the shape of the display panel 100 in a plan view, but the present disclosure is not limited thereto.

The display panel 100 may include a display area DAA that displays an image and a non-display area NDA that does not display an image, as illustrated in FIG. 2.

The display area DAA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1 and may be disposed along the second direction DR2. The plurality of data lines DL may extend in the second direction DR2 and may be disposed along the first direction DR1.

The plurality of scan lines SL includes a plurality of write scan lines GWL, a plurality of control scan lines GCL, and a plurality of bias scan lines EBL. The plurality of emission control lines EL include a plurality of first emission control lines EL1 and a plurality of second emission control lines EL2.

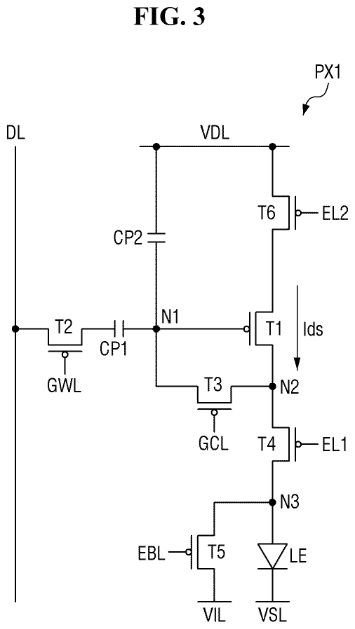

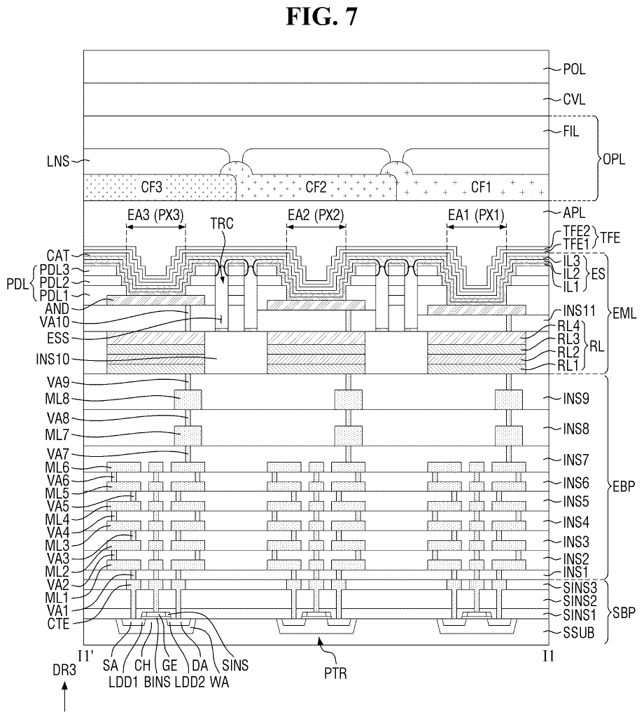

Each of a plurality of unit pixels UPX includes a plurality of pixels PX1, PX2, and PX3. The plurality of pixels PX1, PX2, and PX3 may include a plurality of pixel transistors as illustrated in FIG. 3, and the plurality of pixel transistors may be formed by a semiconductor process and may be disposed on a semiconductor substrate SSUB (see FIG. 7). For example, a plurality of pixel transistors of a data driver 700 may be formed as complementary metal oxide semiconductors (CMOSs).

Each of the plurality of pixels PX1, PX2, and PX3 may be connected to one of the plurality of write scan lines GWL, one of the plurality of control scan lines GCL, one of the plurality of bias scan lines EBL, one of the plurality of first emission control lines EL1, one of the plurality of second emission control lines EL2, and one of the plurality of data lines DL. Each of the plurality of pixels PX1, PX2, and PX3 may receive a data voltage of the data line DL according to a write scan signal of the write scan line GWL, and allow a light emitting element to emit light according to the data voltage.

The non-display area NDA includes a scan driver 610, an emission driver 620, and a data driver 700.

The scan driver 610 includes a plurality of scan transistors, and the emission driver 620 includes a plurality of light emitting transistors. The plurality of scan transistors and the plurality of light emitting transistors may be formed by a semiconductor process and may be formed on a semiconductor substrate SSUB (see FIG. 7). For example, the plurality of scan transistors and the plurality of light emitting transistors may be formed as CMOSs. It has been illustrated in FIG. 2 that the scan driver 610 is disposed on the left side of the display area DAA and the emission driver 620 is disposed on the right side of the display area DAA, but the present disclosure is not limited thereto. For example, the scan drivers 610 and the emission drivers 620 may be disposed on both the left and right sides of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing controller 400. The write scan signal output unit 611 may generate write scan signals according to the scan timing control signal SCS of the timing controller 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines EBL.

The emission driver 620 includes a first emission control driver 621 and a second emission control driver 622. Each of the first emission control driver 621 and the second emission control driver 622 may receive an emission timing control signal ECS from the timing controller 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include a plurality of data transistors, and the plurality of data transistors may be formed by a semiconductor process and may be formed on a semiconductor substrate SSUB (see FIG. 7). For example, the plurality of data transistors may be formed as CMOSs.

The data driver 700 may receive digital video data DATA and a data timing control signal DCS from the timing controller 400. The data driver 700 converts the digital video data DATA into analog data voltages according to the data timing control signal DCS and outputs the analog data voltages to the data lines DL. In this case, the pixels PX1, PX2, and PX3 may be selected by the write scan signals of the scan driver 610, and the data voltages may be supplied to the selected pixels PX1, PX2, and PX3.

The heat dissipation layer 200 may overlap the display panel 100 in a third direction DR3, which is a thickness direction of the display panel 100. The heat dissipation layer 200 may be disposed on one surface, for example, a rear surface, of the display panel 100. The heat dissipation layer 200 serves to dissipate heat generated from the display panel 100. The heat dissipation layer 200 may include a metal layer made of silver (Ag), copper (Cu), and/or aluminum (Al) having high thermal conductivity. In one or more other embodiments, the heat dissipation layer 200 may include a layer made of graphite, silver (Ag), copper (Cu), and/or aluminum (AI) having high thermal conductivity.

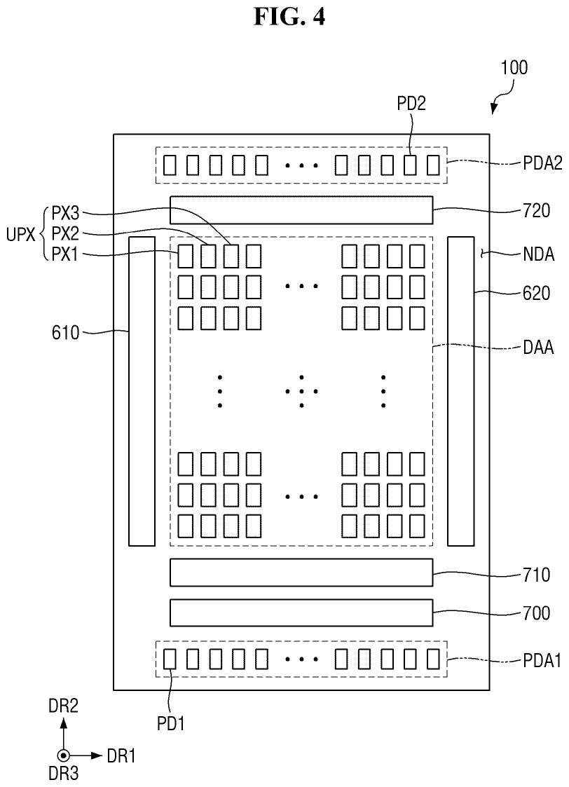

The circuit board 300 may be electrically connected to a plurality of first pads PD1 (see FIG. 4) of a first pad unit PDA1 (see FIG. 4) of the display panel 100 using a conductive adhesive member such as an anisotropic conductive film. The circuit board 300 may be a flexible printed circuit board (FPCB) or a flexible film having a flexible material. It has been illustrated in FIG. 1 that the circuit board 300 is unbent, but the circuit board 300 may be bent. In this case, one end of the circuit board 300 may be disposed on the rear surface of the display panel 100 and/or a rear surface of the heat dissipation layer 200. One end of the circuit board 300 may be an end opposite to the other end of the circuit board 300 connected to the plurality of first pads PD1 (see FIG. 4) of the first pad unit PDA1 (see FIG. 4) of the display panel 100 using the conductive adhesive member.

The timing controller 400 may receive digital video data and timing signals from the outside. The timing controller 400 may generate the scan timing control signal SCS, the emission timing control signal ECS, and the data timing control signal DCS for controlling the display panel 100 according to the timing signals. The timing controller 400 may output the scan timing control signal SCS to the scan driver 610 and output the emission timing control signal ECS to the emission driver 620. The timing controller 400 may output the digital video data DATA and the data timing control signal DCS to the data driver 700.

The power supply unit 500 may generate a plurality of panel driving voltages according to an external source voltage. For example, the power supply unit 500 may generate a first driving voltage VSS, a second driving voltage VDD, a third driving voltage VINT, and a reference voltage VREF, and supply the first driving voltage VSS, the second driving voltage VDD, the third driving voltage VINT, and the reference voltage VREF, to the display panel 100. The first driving voltage VSS, the second driving voltage VDD, and the third driving voltage VINT will be described later with reference to FIG. 3.

Each of the timing controller 400 and the power supply unit 500 may be formed as an integrated circuit (IC) and attached to one surface of the circuit board 300. In this case, the scan timing control signal SCS, the emission timing control signal ECS, the digital video data DATA, and the data timing control signal DCS of the timing controller 400 may be supplied to the display panel 100 through the circuit board 300. In addition, the first driving voltage VSS, the second driving voltage VDD, and the third driving voltage VINT of the power supply unit 500 may be supplied to the display panel 100 through the circuit board 300.

Alternatively, each of the timing controller 400 and the power supply unit 500 may be disposed in the non-display area NDA of the display panel 100, similar to the scan driver 610, the emission driver 620, and the data driver 700. In this case, the timing controller 400 may include a plurality of timing transistors, and the power supply unit 500 may include a plurality of power transistors. The plurality of timing transistors and the plurality of power transistors may be formed by a semiconductor process and may be formed on a semiconductor substrate SSUB (see FIG. 7). For example, the plurality of timing transistors and the plurality of power transistors may be formed as CMOSs. Each of the timing controller 400 and the power supply unit 500 may be disposed between the data driver 700 and the first pad unit PDA1 (see FIG. 4).

FIG. 3 is an equivalent circuit diagram of a first pixel according to one or more embodiments.

Referring to FIG. 3, a first pixel PX1 may be connected to a write scan line GWL, a control scan line GCL, a bias scan line EBL, a first emission control line EL1, a second emission control line EL2, and a data line DL. In addition, the first pixel PX1 may be connected to a first driving voltage line VSL to which a first driving voltage VSS corresponding to a low potential voltage is applied, a second driving voltage line VDL to which a second driving voltage VDD corresponding to a high potential voltage is applied, and a third driving voltage line VIL to which a third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be a voltage lower than the third driving voltage VINT. The second driving voltage VDD may be a voltage higher than the third driving voltage VINT.

The first pixel PX1 includes a plurality of transistors T1 to T6, a light emitting element LE, a first capacitor CP1, and a second capacitor CP2.

The light emitting element LE emits light according to a driving current Ids flowing through a channel of a first transistor T1. An amount of light emitted from the light emitting element LE may be proportional to the driving current Ids. The light emitting element LE may be disposed between a fourth transistor T4 and the first driving voltage line VSL. A first electrode of the light emitting element LE may be connected to a drain electrode of the fourth transistor T4, and a second electrode of the light emitting element LE may be connected to the first driving voltage line VSL. The first electrode of the light emitting element LE may be an anode electrode, and the second electrode of the light emitting element LE may be a cathode electrode. The light emitting element LE may be an organic light emitting diode (OLED) including a first electrode, a second electrode, and an organic light emitting layer disposed between the first electrode and the second electrode, but the present disclosure is not limited thereto. For example, the light emitting element LE may be an inorganic light emitting element including a first electrode, a second electrode, and an inorganic semiconductor disposed between the first electrode and the second electrode, and in this case, the light emitting element LE may be a micro light emitting diode.

The first transistor T1 may be a driving transistor controlling a source-drain current Ids (hereinafter referred to as a “driving current”) flowing between a source electrode and a drain electrode according to a voltage applied to a gate electrode of the first transistor T1 thereof. The first transistor T1 includes the gate electrode connected to a first node N1, the source electrode connected to a drain electrode of a sixth transistor T6, and the drain electrode connected to a second node N2.

A second transistor T2 may be disposed between one electrode of the first capacitor CP1 and the data line DL. The second transistor T2 is turned on by a write scan signal of the write scan line GWL to connect one electrode of the first capacitor CP1 to the data line DL. For this reason, a data voltage of the data line DL may be applied to one electrode of the first capacitor CP1. The second transistor ST2 includes a gate electrode connected to the write scan line GWL, a source electrode connected to the data line DL, and a drain electrode connected to one electrode of the first capacitor CP1.

A third transistor T3 may be disposed between the first node N1 and the second node N2. The third transistor T3 is turned on by a write control signal of the write control line GCL to connect the first node N1 to the second node N2. For this reason, the gate electrode and the drain electrode of the first transistor T1 are connected to each other, and thus, the first transistor T1 may operate like a diode (e.g., the first transistor T1 may be diode-connected). The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by a first emission control signal of the first emission control line EL1 to connect the second node N2 to the third node N3. For this reason, the driving current of the first transistor T1 may be supplied to the light emitting element LE. The fourth transistor T4 includes a gate electrode connected to the first emission control line EL1, a source electrode connected to the second node N2, and the drain electrode connected to the third node N3.

A fifth transistor T5 may be disposed between the third node N3 and the third driving voltage line VIL. The fifth transistor T5 is turned on by a bias scan signal of the bias scan line EBL to connect the third node N3 to the third driving voltage line VIL. For this reason, the third driving voltage VINT of the third driving voltage line VIL may be applied to the first electrode of the light emitting element LE. The fifth transistor T5 includes a gate electrode connected to the bias scan line EBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by a second emission control signal of the second emission control line EL2 to connect the source electrode of the first transistor T1 to the second driving voltage line VDL. For this reason, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and the drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and the other electrode connected to the second driving voltage line VDL.

The first node N1 is a contact point between the gate electrode of the first transistor T1, the drain electrode of the third transistor T3, the other electrode of the first capacitor CP1, and one electrode of the second capacitor CP2. The second node N2 is a contact point between the drain electrode of the first transistor T1, the source electrode of the third transistor T3, and the source electrode of the fourth transistor T4. The third node N3 is a contact point between the drain electrode of the fourth transistor T4, the source electrode of the fifth transistor T5, and the first electrode of the light emitting element LE.

Each of the first to sixth transistors T1 to T6 may be a metal oxide semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. Alternatively, some of the first to sixth transistors T1 to T6 may be P-type MOSFETs, and the others of the first to sixth transistors T1 to T6 may be N-type MOSFETs.

It has been illustrated in FIG. 3 that the first pixel PX1 includes six transistors T1 to T6 and two capacitors CP1 and CP2, but it is to be noted that an equivalent circuit diagram of the first pixel PX1 is not limited to that illustrated in FIG. 3. For example, the numbers of transistors and capacitors of the first pixel PX1 are not limited to those illustrated in FIG. 3.

In addition, an equivalent circuit diagram of a second pixel PX2 and an equivalent circuit diagram of a third pixel PX3 may be substantially the same as the equivalent circuit diagram of the first pixel PX1 described with reference to FIG. 3. Therefore, a description of the equivalent circuit diagram of the second pixel PX2 and the equivalent circuit diagram of the third pixel PX3 is omitted in the present disclosure.

FIG. 4 is a layout diagram illustrating an example of a display panel according to one or more embodiments.

Referring to FIG. 4, the display area DAA of the display panel 100 according to one or more embodiments includes a plurality of pixels PX arranged in a matrix form. The non-display area NDA of the display panel 100 according to one or more embodiments includes a scan driver 610, an emission driver 620, a data driver 700, a first distribution circuit 710, a second distribution circuit 720, a first pad unit PDA1, and a second pad unit PDA2.

The scan driver 610 may be disposed on a first side of the display area DAA, and the emission driver 620 may be disposed on a second side of the display area DAA. For example, the scan driver 610 may be disposed on one side of the display area DAA in the first direction DR1, and the emission driver 620 may be disposed on the other side of the display area DAA in the first direction DR1. That is, the scan driver 610 may be disposed on the left side of the display area DAA, and the emission driver 620 may be disposed on the right side of the display area DAA. However, the present disclosure is not limited thereto, and the scan drivers 610 and the emission drivers 620 may be disposed on both the first and second sides of the display area DAA.

The first pad unit PDA1 may include a plurality of first pads PD1 connected to pads or bumps of the circuit board 300 through a conductive adhesive member. The first pad unit PDA1 may be disposed on a third side of the display area DAA. For example, the first pad unit PDA1 may be disposed on one side of the display area DAA in the second direction DR2.

The first pad unit PDA1 may be disposed outside the data driver 700 in the second direction DR2. That is, the first pad unit PDA1 may be disposed closer to an edge of the display panel 100 than the data driver 700 is.

The second pad unit PDA2 may include a plurality of second pads PD2 corresponding to inspection pads that inspect whether or not the display panel 100 operates normally. The plurality of second pads PD2 may be connected to a jig or a probe pin or connected to a circuit board for inspection in an inspection process. The circuit board for inspection may be a printed circuit board made of a rigid material or a flexible printed circuit board (FPCB) made of a flexible material.

The first distribution circuit 710 distributes data voltages applied through the first pad unit PDA1 to a plurality of data lines DL. For example, the first distribution circuit 710 may distribute data voltages applied through one first pad PD1 of the first pad unit PDA1 to P data lines DL (P is a positive integer of 2 or more), and for this reason, the number of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, the first distribution circuit 710 may be disposed on the lower side of the display area DAA.

The second distribution circuit 720 distributes signals applied through the second pad unit PDA2 to the scan driver 610, the emission driver 620, and the data lines DL. The second pad unit PDA2 and the second distribution circuit 720 may be components for inspecting an operation of each of the pixels PX of the display area DAA. The second distribution circuit 720 may be disposed on a fourth side of the display area DAA of the display panel 100. For example, the second distribution circuit 720 may be disposed on the other side of the display area DAA in the second direction DR2. That is, the second distribution circuit 720 may be disposed on the upper side of the display area DAA.

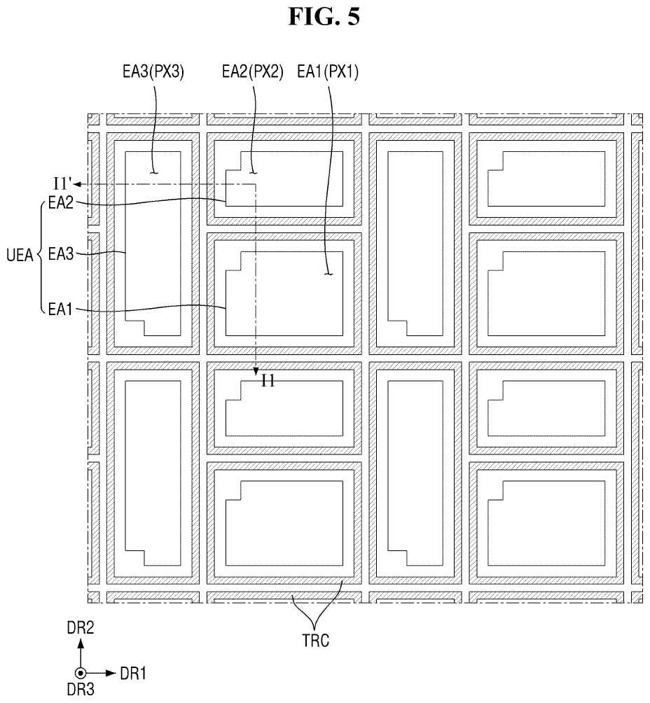

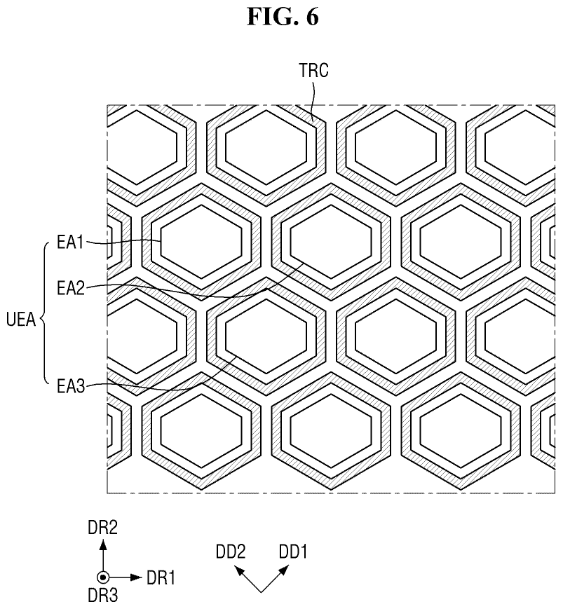

FIGS. 5 and 6 are layout diagrams illustrating embodiments of a display area of FIG. 4.

Referring to FIGS. 5 and 6, each of the plurality of unit pixels UPX includes a first emission area EA1 that is an emission area of the first pixel PX1, a second emission area EA2 that is an emission area of the second pixel PX2, and a third emission area EA3 that is an emission area of the third pixel PX3. In other words, the unit pixel UPX may include a unit emission area UEA, and this unit emission area UEA includes the above-described first emission area EA1, second emission area EA2, and third emission area EA3.

Referring to FIGS. 5 and 6, each of the plurality of unit pixels UPX includes a first emission area EA1 that is an emission area of the first pixel PX1, a second emission area EA2 that is an emission area of the second pixel PX2, and a third emission area EA3 that is an emission area of the third pixel PX3.

Each of the first emission area EA1, the second emission area EA2, and the third emission area EA3 may have a polygonal shape, a circular shape, an elliptical shape, and/or an irregular shape in a plan view.

A maximum length of the third emission area EA3 in the first direction DR1 may be smaller than a maximum length of the first emission area EA1 in the first direction DR1 and a maximum length of the second emission area EA2 in the first direction DR1. The maximum length of the first emission area EA1 in the first direction DR1 and the maximum length of the second emission area EA2 in the first direction DR1 may be substantially the same as each other.

A maximum length of the third emission area EA3 in the second direction DR2 may be greater than a maximum length of the first emission area EA1 in the second direction DR2 and a maximum length of the second emission area EA2 in the second direction DR2. The maximum length of the first emission area EA1 in the second direction DR2 may be greater than the maximum length of the second emission area EA2 in the second direction DR2. The maximum length of the first emission area EA1 in the second direction DR2 may be smaller than the maximum length of the third emission area EA3 in the second direction DR2.

Each of the first emission area EA1, the second emission area EA2, and the third emission area EA3 may have a hexagonal shape including six straight lines, in a plan view, as illustrated in FIGS. 5 and 6, but the present disclosure is not limited thereto. Each of the first emission area EA1, the second emission area EA2, and the third emission area EA3 may have polygonal shapes other than the hexagonal shape, a circular shape, an elliptical shape, or an irregular shape in a plan view.

As illustrated in FIG. 5, in each of the plurality of unit pixels UPX, the first emission area EA1 and the second emission area EA2 may neighbor to each other in the second direction DR2. In addition, the first emission area EA1 and the third emission area EA3 may neighbor to each other in the first direction DR1. In addition, the second emission area EA2 and the third emission area EA3 may neighbor to each other in the first direction DR1. An area of the first emission area EA1, an area of the second emission area EA2, and an area of the third emission area EA3 may be different from each other.

Alternatively, as illustrated in FIG. 6, the first emission area EA1 and the second emission area EA2 may neighbor to each other in the first direction DR1, but the second emission area EA2 and the third emission area EA3 may neighbor to each other in a first diagonal direction DD1, and the first emission area EA1 and the third emission area EA3 may neighbor to each other in a second diagonal direction DD2. The first diagonal direction DD1 is a direction between the first direction DR1 and the second direction DR2 and may refer to a direction inclined by 45° with respect to the first direction DR1 and the second direction DR2, and the second diagonal direction DD2 may be a direction orthogonal to the first diagonal direction DD1

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may indicate that a main peak wavelength of the light is included in a wavelength band of approximately 370 nm to 460 nm, the green wavelength band may indicate that a main peak wavelength of the light is included in a wavelength band of approximately 480 nm to 560 nm, and the red wavelength band may indicate that a main peak wavelength of the light is included in a wavelength band of approximately 600 nm and 750 nm.

It has been illustrated in FIGS. 5 and 6 that each of the plurality of unit pixels UPX includes three emission areas EA1, EA2, and EA3, but the present disclosure is not limited thereto. That is, each of the plurality of unit pixels UPX may also include four emission areas.

In addition, an arrangement of the emission areas of the plurality of unit pixels UPX is not limited to those illustrated in FIGS. 5 and 6. For example, the emission areas of the plurality of unit pixels UPX may be disposed in a stripe structure in which the emission areas are arranged along the first direction DR1, a PENTILE® structure in which the emission areas have a diamond arrangement, or a hexagonal structure in which emission areas having a hexagonal shape in a plan view are arranged as illustrated in FIG. 6. PENTILE® and Diamond Pixel® are registered trademarks of Samsung Display Co., Ltd., Republic of Korea.

FIG. 7 is a cross-sectional view illustrating an example of the display panel taken along the line I1-I1′ of FIG. 5.

Referring to FIG. 7, the display panel 100 includes a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, and/or a silicon-germanium substrate. The semiconductor substrate SSUB may be a substrate doped with first-type impurities. A plurality of well regions WA may be disposed in an upper surface of the semiconductor substrate SSUB. The plurality of well regions WA may be regions doped with second-type impurities. The second-type impurities may be different from the first-type impurities described above. For example, when the first-type impurities are P-type impurities, the second-type impurities may be N-type impurities. Alternatively, when the first-type impurities are N-type impurities, the second-type impurities may be P-type impurities.

Each of the plurality of well regions WA includes a source region SA corresponding to a source electrode of the pixel transistor PTR, a drain region DA corresponding to a drain electrode of the pixel transistor PTR, and a channel region CH disposed between the source region SA and the drain region DA.

A bottom insulating film BINS may be disposed between a gate electrode GE and the well region WA. Side surface insulating films SINS may be disposed on side surfaces of the gate electrode GE. The side surface insulating films SINS may be disposed on the bottom insulating film BINS.

Each of the source region SA and the drain region DA may be a region doped with the first-type impurities. A gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA and a second low-concentration impurity region LDD2 disposed between the channel region CH and the drain region DA. The first low-concentration impurity region LDD1 may be a region having a lower impurity concentration than the source region SA due to the bottom insulating film BINS. The second low-concentration impurity region LDD2 may be a region having a lower impurity concentration than the drain region DA due to the bottom insulating film BINS. A distance between the source region SA and the drain region DA may increase by the first low-concentration impurity region LDD1 and the second low-concentration impurity region LDD2. Therefore, a length of the channel region CH of each of the pixel transistors PTR may increase, and thus, punch-through and hot carrier phenomena caused by a short channel may be prevented.

A first semiconductor insulating film SINS1 may be disposed on the semiconductor substrate SSUB. The first semiconductor insulating film SINS1 may be formed as a silicon carbonitride (SiCN) and/or silicon oxide (SiOₓ)-based inorganic film, but the present disclosure is not limited thereto.

A second semiconductor insulating film SINS2 may be disposed on the first semiconductor insulating film SINS1. The second semiconductor insulating film SINS2 may be formed as a silicon oxide (SiOₓ)-based inorganic film, but the present disclosure is not limited thereto.

The plurality of contact terminals CTE may be disposed on the second semiconductor insulating film SINS2. Each of the plurality of contact terminals CTE may be connected to one of the gate electrode GE, the source region SA, and the drain region DA of each of the pixel transistors PTR through a hole penetrating through the first semiconductor insulating film SINS1 and the second semiconductor insulating film SINS2. Each of the plurality of contact terminals CTE may be made of copper (Cu), aluminum (Al), tungsten (W), molybdenum (Mo), chromium (Cr), gold (Au), titanium (Ti), nickel (Ni), and/or neodymium (Nd), and/or alloys thereof.

A third semiconductor insulating film SINS3 may be disposed on side surfaces of each of the plurality of contact terminals CTE on the second semiconductor insulating film SINS2. An upper surface of each of the plurality of contact terminals CTE may be exposed without being covered by the third semiconductor insulating film SINS3. The third semiconductor insulating film SINS3 may be formed as a silicon oxide (SiOₓ)-based inorganic film, but the present disclosure is not limited thereto.

The semiconductor substrate SSUB may be replaced with a glass substrate and/or a polymer resin substrate such as a polyimide substrate. In this case, thin film transistors may be disposed on the glass substrate and/or the polymer resin substrate. The glass substrate may be a rigid substrate that is not bent, and the polymer resin substrate may be a flexible substrate that may be bent and/or curved.

The light emitting element backplane EBP includes a plurality of conductive layers ML1 to ML8, a plurality of vias VA1 to VA9, and a plurality of insulating films INS1 to INS9. In the light emitting element backplane EBP, the plurality of insulating films INS1 to INS9 may be disposed between first to eighth conductive layers ML1 to ML8.

The first to eighth conductive layers ML1 to ML8 serve to implement a circuit of the first pixel PX1 illustrated in FIG. 3 by connecting the plurality of contact terminals CTE exposed from the semiconductor backplane SBP to each other. For example, only the first to sixth transistors T1 to T6 are formed in the semiconductor backplane SBP, and the connection between the first to sixth transistors T1 to T6 and the formation of the first capacitor CP1 and the second capacitor CP2 are performed through the first to eighth conductive layers ML1 to ML8. In addition, the connection between a drain region corresponding to a drain electrode of the fourth transistor T4, a source region corresponding to a source electrode of the fifth transistor T5, and a first electrode of a light emitting element LE is also performed through the first to eighth conductive layers ML1 to ML8.

A first insulating film INS1 may be disposed on the semiconductor backplane SBP. Each of first vias VA1 may penetrate through the first insulating film INS1 to be connected to the contact terminal CTE exposed from the semiconductor backplane SBP. Each of the first conductive layers ML1 may be disposed on the first insulating film INS1 and may be connected to the first via VA1.

A second insulating film INS2 may be disposed on the first insulating film INS1 and the first conductive layers ML1. Each of second vias VA2 may penetrate through the second insulating film INS2 to be connected to the exposed first conductive layer ML1. Each of the second conductive layers ML2 may be disposed on the second insulating film INS2 and may be connected to the second via VA2.

A third insulating film INS3 may be disposed on the second insulating film INS2 and the second conductive layers ML2. Each of third vias VA3 may penetrate through the third insulating film INS3 to be connected to the exposed second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of fourth vias VA4 may penetrate through the fourth insulating film INS4 to be connected to the exposed third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of fifth vias VA5 may penetrate through the fifth insulating film INS5 to be connected to the exposed fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of sixth vias VA6 may penetrate through the sixth insulating film INS6 to be connected to the exposed fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of seventh vias VA7 may penetrate through the seventh insulating film INS7 to be connected to the exposed sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of eighth vias VA8 may penetrate through the eighth insulating film INS8 to be connected to the exposed seventh conductive layer ML7. Each of the eighth conductive layers ML8 may be disposed on the eighth insulating film INS8 and may be connected to the eighth via VA8.

The first to eighth conductive layers ML1 to ML8 and the first to eighth vias VA1 to VA8 may be made of substantially the same material. Each of the first to eighth conductive layers ML1 to ML8 and the first to eighth vias VA1 to VA8 may be made of copper (Cu), aluminum (Al), tungsten (W), molybdenum (Mo), chromium (Cr), gold (Au), titanium (Ti), nickel (Ni), and/or neodymium (Nd), and/or alloys thereof. The first to eighth vias VA1 to VA8 may be made of substantially the same material. The first to eighth insulating films INS1 to INS8 may be formed as silicon oxide (SiOₓ)-based inorganic films, but the present disclosure is not limited thereto.

Each of a thickness of the first conductive layer ML1, a thickness of the second conductive layer ML2, a thickness of the third conductive layer ML3, a thickness of the fourth conductive layer ML4, a thickness of the fifth conductive layer ML5, and a thickness of the sixth conductive layer ML6 may be greater than each of a thickness of the first via VA1, a thickness of the second via VA2, a thickness of the third via VA3, a thickness of the fourth via VA4, a thickness of the fifth via VA5, and a thickness of the sixth via VA6. Each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same as each other. For example, the thickness of the first conductive layer ML1 may be approximately 1360 Å, each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be approximately 1440 Å, and each of the thickness of the first via VA1, the thickness of the second via VA2, the thickness of the third via VA3, the thickness of the fourth via VA4, the thickness of the fifth via VA5, and the thickness of the sixth via VA6 may be approximately 1150 Å.

Each of a thickness of the seventh conductive layer ML7 and a thickness of the eighth conductive layer ML8 may be greater than each of the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. Each of the thickness of the seventh conductive layer ML7 and the eighth conductive layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same as each other. For example, each of the thickness of the seventh conductive layer ML7 and the thickness of the eighth conductive layer ML8 may be approximately 9000 Å. Each of the thickness of the seventh via VA7 and the thickness of the eighth via VA8 may be approximately 6000 Å.

A ninth insulating film INS9 may be disposed on the eighth insulating film INS8 and the eighth conductive layer ML8. The ninth insulating film INS9 may be formed as a silicon oxide (SiOₓ)-based inorganic film, but the present disclosure is not limited thereto.

Each of ninth vias VA9 may penetrate through the ninth insulating film INS9 to be connected to the exposed eighth conductive layer ML8. Each of the ninth vias VA9 may be made of copper (Cu), aluminum (Al), tungsten (W), molybdenum (Mo), chromium (Cr), gold (Au), titanium (Ti), nickel (Ni), and/or neodymium (Nd), and/or alloys thereof. A thickness of the ninth via VA9 may be approximately 16500 Å.

The display element layer EML may be disposed on the light emitting element backplane EBP. The display element layer EML may include a reflective electrode layer RL, tenth and eleventh insulating films INS10 and INS11, tenth vias VA10, light emitting elements LE each including a first electrode AND, a light emitting stack ES, and a second electrode CAT, a pixel defining film PDL, and a plurality of trenches TRC.

The reflective electrode layer RL may be disposed on the ninth insulating film INS9. The reflective electrode layer RL may include one or more reflective electrodes RL1, RL2, RL3, and RL4. For example, the reflective electrode layer RL may include first to fourth reflective electrodes RL1, RL2, RL3, and RL4 as illustrated in FIG. 7.

Each of the first reflective electrodes RL1 may be disposed on the ninth insulating film INS9 and may be connected to the ninth via VA9. Each of the first reflective electrodes RL1 may be made of copper (Cu), aluminum (Al), tungsten (W), molybdenum (Mo), chromium (Cr), gold (Au), titanium (Ti), nickel (Ni), and/or neodymium (Nd), and/or alloys thereof. For example, each of the first reflective electrodes RL1 may include titanium nitride (TiN).

Each of the second reflective electrodes RL2 may be disposed on the first reflective electrode RL1. Each of the second reflective electrodes RL2 may be made of copper (Cu), aluminum (Al), tungsten (W), molybdenum (Mo), chromium (Cr), gold (Au), titanium (Ti), nickel (Ni), and/or neodymium (Nd), and/or alloys thereof. For example, each of the second reflective electrodes RL2 may include aluminum (Al).

Each of the third reflective electrodes RL3 may be disposed on the second reflective electrode RL2. Each of the third reflective electrodes RL3 may be made of copper (Cu), aluminum (Al), tungsten (W), molybdenum (Mo), chromium (Cr), gold (Au), titanium (Ti), nickel (Ni), and/or neodymium (Nd), and/or alloys thereof. For example, each of the third reflective electrodes RL3 may include titanium nitride (TiN).

Each of the fourth reflective electrodes RL4 may be disposed on the third reflective electrode RL3. Each of the fourth reflective electrodes RL4 may be made of copper (Cu), aluminum (Al), tungsten (W), molybdenum (Mo), chromium (Cr), gold (Au), titanium (Ti), nickel (Ni), and/or neodymium (Nd), and/or alloys thereof. For example, each of the fourth reflective electrodes RL4 may include titanium (Ti).

Because the second reflective electrodes RL2 are electrodes substantially reflecting light from the light emitting elements LE, in one or more embodiments, a thickness of the second reflective electrode RL2 may be greater than a thickness of the first reflective electrode RL1, a thickness of the third reflective electrode RL3, and a thickness of the fourth reflective electrode RL4. For example, in one or more embodiments, the thickness of the first reflective electrode RL1, the third reflective electrode RL3, and the fourth reflective electrode RL4 may be approximately 100 Å, and the thickness of the second reflective electrode RL2 may be approximately 850 Å.

The tenth insulating film INS10 may be disposed on the ninth insulating film INS9. The tenth insulating film INS10 may be disposed between the reflective electrode layers RL adjacent to each other in a horizontal direction (e.g., the first direction DR1 and/or the second direction DR2). In one or more embodiments, the tenth insulating film INS10 may be disposed on the reflective electrode layer RL in the third pixel PX3. The tenth insulating film INS10 may be formed as a silicon oxide (SiOₓ)-based inorganic film, but the present disclosure is not limited thereto.

The eleventh insulating film INS11 may be disposed on the tenth insulating film INS10 and the reflective electrode layer RL. The eleventh insulating film INS11 may be formed as a silicon oxide (SiOₓ)-based inorganic film, but the present disclosure is not limited thereto. The tenth insulating film INS10 and the eleventh insulating film INS11 may be optical auxiliary layers through which light reflected by the reflective electrode layer RL from among light emitted from the light emitting elements LE passes.

In one or more embodiments, in order to adjust a resonance distance of the light emitted from the light emitting elements LE in at least one of the first pixel PX1, the second pixel PX2, and the third pixel PX3, the tenth insulating film INS10 and the eleventh insulating film INS11 may not be disposed below the first electrode AND of the first pixel PX1. In one or more embodiments, the first electrode AND of the first pixel PX1 may be directly disposed on the reflective electrode layer RL. In one or more embodiments, the eleventh insulating film INS11 may be disposed below the first electrode AND of the second pixel PX2. The tenth insulating film INS10 and the eleventh insulating film INS11 may be disposed below the first electrode AND of the third pixel PX3.

In summary, a distance between the first electrode AND and the reflective electrode layer RL may be different in each of the first pixel PX1, the second pixel PX2, and the third pixel PX3. That is, in order to adjust a distance from the reflective electrode layer RL to the second electrode CAT according to a main wavelength of light emitted from each of the first pixel PX1, the second pixel PX2, and third pixel PX3, the presence or absence of the tenth insulating film INS10 and the eleventh insulating film INS11 may be set in each of the first pixel PX1, the second pixel PX2, and the third pixel PX3. For example, it has been illustrated in FIG. 7 that a distance between the first electrode AND and the reflective electrode layer RL in the third pixel PX3 is greater than a distance between the first electrode AND and the reflective electrode layer RL in the second pixel PX2 and a distance between the first electrode AND and the reflective electrode layer RL in the first pixel PX1 and the distance between the first electrode AND and the reflective electrode layer RL in the second pixel PX2 is greater than the distance between the first electrode AND and the reflective electrode layer RL in the first pixel PX1, but the present disclosure is not limited thereto.

In addition, the tenth insulating film INS10 and the eleventh insulating film INS11 have been illustrated in an embodiment of the present disclosure, but a twelfth insulating film disposed below the first electrode AND of the first pixel PX1 may be added. In this case, the eleventh insulating film INS11 and the twelfth insulating film may be disposed below the first electrode AND of the second pixel PX2, and the tenth insulating film INS10, the eleventh insulating film INS11, and the twelfth insulating film may be disposed below the first electrode AND of the third pixel PX3.

Each of the tenth vias VA10 may penetrate through the eleventh insulating film INS11 in the first to third pixels PX1 to PX3 to be connected to the exposed fourth reflective electrode RL4. In one or more embodiments, each of the tenth vias VA10 may penetrate through the tenth insulating film INS10 and/or the eleventh insulating film INS11 in the second pixel PX2 and the third pixel PX3 to be connected to the exposed fourth reflective electrode RL4. Each of the tenth vias VA10 may be made of copper (Cu), aluminum (Al), tungsten (W), molybdenum (Mo), chromium (Cr), gold (Au), titanium (Ti), nickel (Ni), and/or neodymium (Nd), and/or alloys thereof. A thickness of the tenth via VA10 in the second pixel PX2 may be smaller than a thickness of the tenth via VA10 in the third pixel PX3.

The first electrode AND of each of the light emitting elements LE may be disposed on the eleventh insulating film INS11 and may be connected to the tenth via VA10. In one or more embodiments, the first electrode AND of each of the light emitting elements LE may be disposed on the tenth insulating film INS10. The first electrode AND of each of the light emitting elements LE may be connected to the drain region DA or the source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be made of copper (Cu), aluminum (Al), tungsten (W), molybdenum (Mo), chromium (Cr), gold (Au), titanium (Ti), nickel (Ni), and/or neodymium (Nd), and/or alloys thereof. For example, the first electrode AND of each of the light emitting elements LE may be made of titanium nitride (TiN).

The pixel defining film PDL may be disposed on a partial area of the first electrode AND of each of the light emitting elements LE. The pixel defining film PDL may cover an edge of the first electrode AND of each of the light emitting elements LE. The pixel defining film PDL serves to partition the first emission areas EA1, the second emission areas EA2, and the third emission areas EA3.

The first emission area EA1 may be defined as an area where the first electrode AND, the light emitting stack ES, and the second electrode CAT are sequentially stacked in the first pixel PX1 to emit light. The second emission area EA2 may be defined as an area where the first electrode AND, the light emitting stack ES, and the second electrode CAT are sequentially stacked in the second pixel PX2 to emit light. The third emission area EA3 may be defined as an area where the first electrode AND, the light emitting stack ES, and the second electrode CAT are sequentially stacked in the third pixel PX3 to emit light.

The pixel defining film PDL may include first to third pixel defining films PDL1, PDL2, and PDL3. The first pixel defining film PDL1 may be disposed on the edge of the first electrode AND of each of the light emitting elements LE and the eleventh insulating film INS11, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed as silicon oxide (SiOₓ)-based inorganic films, but the present disclosure is not limited thereto. Each of a thickness of the first pixel defining film PDL1, a thickness of the second pixel defining film PDL2, and a thickness of the third pixel defining film PDL3 may be approximately 500 Å.

When the first pixel defining film PDL1, the second pixel defining film PDL2, and the third pixel defining film PDL3 are formed as one pixel defining film, a height of the one pixel defining film increases, such that a first encapsulation inorganic film TFE1 may be disconnected due to step coverage. The step coverage refers to a ratio of a degree at which a thin film is coated on an inclined portion to a degree at which a thin film is coated on a flat portion. The lower the step coverage, the more likely it is that the thin film will be disconnected at the inclined portion.

Therefore, in order to prevent the first encapsulation inorganic film TFE1 from being disconnected due to the step coverage, the first pixel defining film PDL1, the second pixel defining film PDL2, and the third pixel defining film PDL3 may have a cross-sectional structure with a step having a staircase shape. For example, a width of the first pixel defining film PDL1 may be greater than a width of the second pixel defining film PDL2 and a width of the third pixel defining film PDL3, and the width of the second pixel defining film PDL2 may be greater than the width of the third pixel defining film PDL3. The width of the first pixel defining film PDL1 refers to a length, in the horizontal direction, of the first pixel defining film PDL1 defined by the first direction DR1 and the second direction DR2.

Each of the plurality of trenches TRC may penetrate through the first pixel defining film PDL1, the second pixel defining film PDL2, and the third pixel defining film PDL3. In addition, each of the plurality of trenches TRC may penetrate through the eleventh insulating film INS11. In one or more embodiments, in each of the plurality of trenches TRC, the tenth insulating film INS10 may have a shape in which a portion thereof is trenched.

At least one trench TRC may be disposed between the pixels PX1, PX2, and PX3 neighboring to each other. It has been illustrated in FIG. 7 that two trenches TRC are disposed between the pixels PX1, PX2, and PX3 neighboring to each other, but the present disclosure is not limited thereto.

The light emitting stack ES may include a plurality of stack layers. It has been illustrated in FIG. 7 that the light emitting stack ES has a three-tandem structure including a first stack layer IL1, a second stack layer IL2, and a third stack layer IL3, but the present disclosure is not limited thereto. For example, the light emitting stack ES may have a two-tandem structure including two intermediate layers.

In the three-tandem structure, the light emitting stack ES may have a tandem structure including a plurality of stack layers IL1, IL2, and IL3 emitting different light. For example, the light emitting stack ES may include a first stack layer IL1 emitting light of a first color, a second stack layer IL2 emitting light of a third color, and a third stack layer IL3 emitting light of a second color. The first stack layer IL1, the second stack layer IL2, and the third stack layer IL3 may be sequentially stacked.

The first stack layer IL1 may have a structure in which a first hole transporting layer, a first organic light emitting layer emitting the light of the first color, and a first electron transporting layer are sequentially stacked. The second stack layer IL2 may have a structure in which a second hole transporting layer, a second organic light emitting layer emitting the light of the third color, and a second electron transporting layer are sequentially stacked. The third stack layer IL3 may have a structure in which a third hole transporting layer, a third organic light emitting layer emitting the light of the second color, and a third electron transporting layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer supplying electrons to the first stack layer IL1 and a P-type charge generation layer supplying holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer supplying electrons to the second stack layer IL2 and a P-type charge generation layer supplying holes to the third stack layer IL3.

The first stack layer IL1 may be disposed on the first electrodes AND and the pixel defining film PDL, and may be disposed on a bottom surface of each of the trenches TRC. Due to the trenches TRC, the first stack layer IL1 may be disconnected between the pixels PX1, PX2, and PX3 neighboring to each other. The second stack layer IL2 may be disposed on the first stack layer IL1. Due to the trenches TRC, the second stack layer IL2 may be disconnected between the pixels PX1, PX2, and PX3 neighboring to each other. A cavity ESS or an empty space may be disposed between the first stack layer IL1 and the second stack layer IL2. The third stack layer IL3 may be disposed on the second stack layer IL2. The third stack layer IL3 may not be disconnected by the trenches TRC, and may be disposed to cover the second stack layer IL2 in each of the trenches TRC. That is, in the three-tandem structure, each of the plurality of trenches TRC may be a structure for disconnecting the first and second stack layers IL1 and IL2, the first charge generation layer, and the second charge generation layer of the display element layer EML between the pixels PX1, PX2, and PX3 neighboring to each other. In addition, in the two-tandem structure, each of the plurality of trenches TRC may be a structure for disconnecting a charge generation layer disposed between a lower intermediate layer and an upper intermediate layer and the lower intermediate layer.

In order to stably disconnect the first and second stack layers IL1 and IL2 of the display element layer EML between the pixels PX1, PX2, and PX3 neighboring to each other, a height of each of the plurality of trenches TRC may be greater than a height of the pixel defining film PDL. The height of each of the plurality of trenches TRC refers to a length of each of the plurality of trenches TRC in the third direction DR3. The height of the pixel defining film PDL refers to a length of the pixel defining film PDL in the third direction DR3. In order to disconnect the first and second intermediate layers IL1 and IL2 of the display element layer EML between the pixels PX1, PX2, and PX3 neighboring to each other, other structures may exist instead of the trenches TRC. For example, instead of the trenches TRC, partition walls having a reverse tapered shape may be disposed on the pixel defining film PDL.

The number of stack layers IL1, IL2, and IL3 emitting the different light is not limited to that illustrated in FIG. 7. For example, the light emitting stack ES may include two intermediate layers. In this case, one of the two intermediate layers may be substantially the same as the first stack layer IL1, and the other of the two intermediate layers may include a second hole transporting layer, a second organic light emitting layer, a third organic light emitting layer, and/or a second electron transporting layer. In this case, a charge generation layer for supplying electrons to one intermediate layer and supplying charges to the other intermediate layer may be disposed between the two intermediate layers.

It has been illustrated in FIG. 7 that the first to third stack layers IL1, IL2, and IL3 are all disposed in the first emission area EA1, the second emission area EA2, and the third emission area EA3, but the present disclosure is not limited thereto. For example, in one or more embodiments, the first stack layer IL1 may be disposed in the first emission area EA1, and may not be disposed in the second emission area EA2 and the third emission area EA3. In addition, the second stack layer IL2 may be disposed in the second emission area EA2, and may not be disposed in the first emission area EA1 and the third emission area EA3. In addition, the third stack layer IL3 may be disposed in the third emission area EA3, and may not be disposed on the first emission area EA1 and the second emission area EA2. In this case, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC. The second electrode CAT may be made of a transparent conductive material (TCO) such as indium tin oxide (ITO) and/or indium zinc oxide (IZO) capable of transmitting light therethrough and/or a semi-transmissive conductive material such as magnesium (Mg), silver (Ag), and/or an alloy of magnesium (Mg) and/or silver (Ag). When the second electrode CAT is made of the semi-transmissive conductive material, light emission efficiency of each of the first to third pixels PX1, PX2, and PX3 may be increased by a micro cavity.

The encapsulation layer TFE may be disposed on the display element layer EML. The encapsulation layer TFE may include at least one inorganic film TFE1 and/or TFE2 in order to prevent oxygen and/or moisture from permeating into the display element layer EML. For example, the encapsulation layer TFE may include a first encapsulation inorganic film TFE1 and a second encapsulation inorganic film TFE2.

The first encapsulation inorganic film TFE1 may be disposed on the second electrode CAT. The first encapsulation inorganic film TFE1 may be formed as multiple films in which one or more inorganic films of a silicon nitride (SiNₓ) layer, a silicon oxynitride (SiON) layer, and/or a silicon oxide (SiOₓ) layer are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed as a titanium oxide (TiOₓ) layer and/or an aluminum oxide (AlOₓ) layer, but the present disclosure is not limited thereto. The second encapsulation inorganic film TFE2 may be formed by an atomic layer deposition (ALD) process. A thickness of the second encapsulation inorganic film TFE2 may be smaller than a thickness of the first encapsulation inorganic film TFE1.

An organic film APL may be a layer for increasing interfacial adhesive strength between the encapsulation layer TFE and the optical layer OPL. The organic film APL may be an organic film made of an acrylic resin, an epoxy resin, a phenolic resin, a polyamide resin, a polyimide resin, and/or the like.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be disposed on the organic film APL.

The first color filter CF1 may overlap the first emission area EA1 of the first pixel PX1. The first color filter CF1 may transmit the light of the first color, that is, the light of the blue wavelength band, therethrough. The blue wavelength band may be approximately 370 nm to 460 nm. Therefore, the first color filter CF1 may transmit the light of the first color from among light emitted from the first emission area EA1 therethrough.

The second color filter CF2 may overlap the second emission area EA2 of the second pixel PX2. The second color filter CF2 may transmit the light of the second color, that is, the light of the green wavelength band, therethrough. The green wavelength band may be approximately 480 nm to 560 nm. Therefore, the second color filter CF2 may transmit the light of the second color from among light emitted from the second emission area EA2 therethrough.

The third color filter CF3 may overlap the third emission area EA3 of the third pixel PX3. The third color filter CF3 may transmit the light of the third color, that is, the light of the red wavelength band, therethrough. The red wavelength band may be approximately 600 nm to 750 nm. Therefore, the third color filter CF3 may transmit the light of the third color from among light emitted from the third emission area EA3 therethrough.

Each of the plurality of lenses LNS may be disposed on each of the first color filter CF1, the second color filter CF2, and the third color filter CF3. Each of the plurality of lenses LNS may be a structure for increasing a ratio of light directed to a front surface of the display device 10. Each of the plurality of lenses LNS may have a cross-sectional shape convex in an upward direction.

The filling layer FIL may be disposed on the plurality of lenses LNS. The filling layer FIL may have a suitable reflective index (e.g., a predetermined refractive index) so that light travels in the third direction DR3 at an interface between the plurality of lenses LNS and the filling layer FIL. In addition, the filling layer FIL may be a planarizing layer. The filling layer FIL may be an organic film made of an acrylic resin, an epoxy resin, a phenolic resin, a polyamide resin, a polyimide resin, and/or the like.

The cover layer CVL may be disposed on the filling layer FIL. The cover layer CVL may be a glass substrate or a polymer resin such as a resin. When the cover layer CVL is the glass substrate, the cover layer CVL may be attached onto the filling layer FIL. In this case, the filling layer FIL may serve to adhere the cover layer CVL. When the cover layer CVL is the glass substrate, the cover layer CVL may serve as an encapsulation substrate. When the cover layer CVL is the polymer resin such as the resin, the cover layer CVL may be directly applied onto the filling layer FIL.

The polarizing plate POL may be disposed on one surface of the cover layer CVL. The polarizing plate POL may be a structure for preventing deterioration in visibility due to external light reflection. The polarizing plate POL may include a linear polarizing plate and a phase retardation film. For example, the phase retardation film may be a λ/4 plate (e.g., a quarter-wave plate), but the present disclosure is not limited thereto. However, when visibility due to external light reflection is sufficiently improved by the first to third color filters CF1, CF2, and CF3, the polarizing plate POL may be omitted.

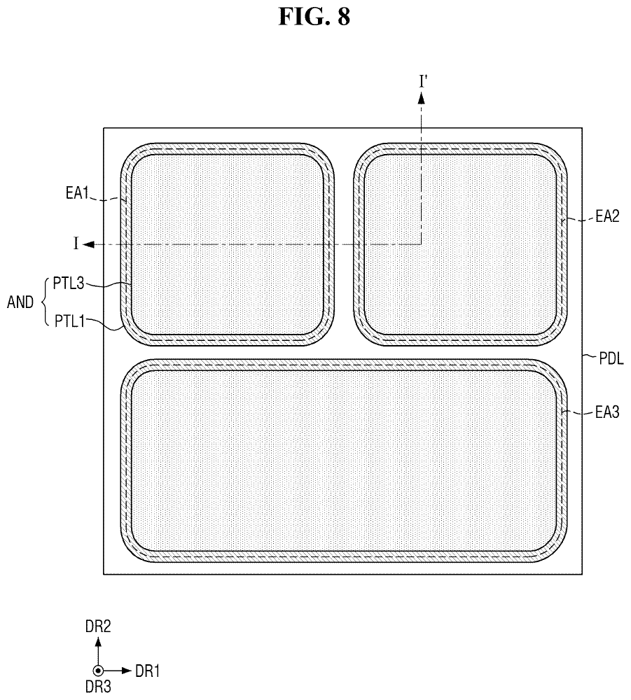

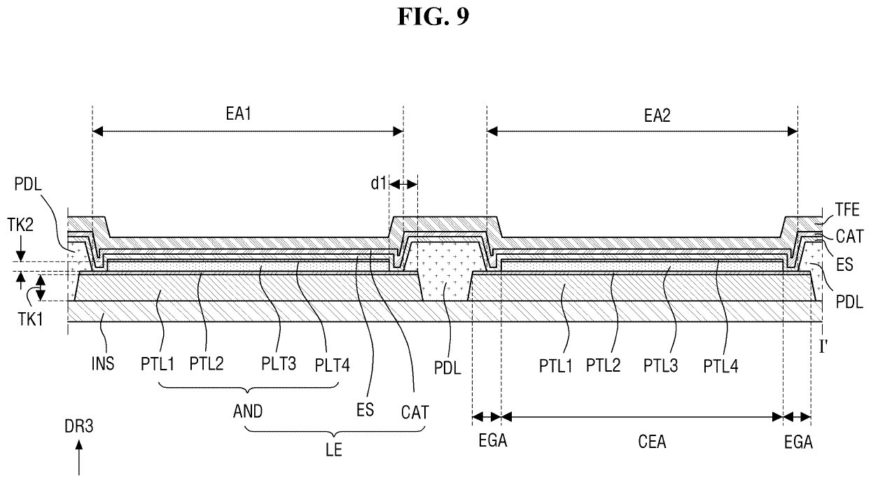

FIG. 8 is a plan view of a display device according to one or more embodiments, and FIG. 9 is a cross-sectional view taken along the line I-I′ of FIG. 8.

As illustrated in FIGS. 8 and 9, a first electrode AND may be disposed correspondingly to each of the emission areas EA1, EA2, and EA3. For example, the first electrode AND may be disposed in the first to third emission areas EA1 to EA3, respectively. The first electrode AND of each of the first to third emission areas EA1 to EA3 may have the same structure, and hereinafter, the first electrode AND of the first emission area will be mainly described.

As illustrated in FIG. 9, the first electrode AND may include a plurality of layers (e.g., pattern layers). For example, the first electrode AND may include a first pattern layer PTL1, a second pattern layer PTL2, a third pattern layer PTL3, and a fourth pattern layer PTL4 sequentially stacked along the third direction DR3.

The first pattern layer PTL1 may be disposed on an insulating layer INS (e.g., the eleventh insulating film INS11). For example, the first pattern layer PTL1 may be disposed between the insulating layer INS and the second pattern layer PTL2. The first pattern layer PTL1 may be electrically connected to a drain region DA of a pixel transistor PTR through at least one via and at least one conductive layer (e.g., the tenth via VA10, the first to fourth reflective electrodes RL1 to RL4, the first to ninth vias VA1 to VA9, the first to eighth conductive layers ML1 to ML8, and the contact terminal CTE). The first pattern layer PTL1 may include metal. For example, the first pattern layer PTL1 may include aluminum (Al). In one or more embodiments, the first pattern layer PTL1 from among the plurality of pattern layers in the first electrode AND may have a greater thickness TK1 than the other pattern layers so that the reflectance of the first electrode AND can be improved. For example, the first pattern layer PTL1 may have a thickness that is four times of a thickness TK2 of the third pattern layer PTL3 or have a thickness greater than four times the thickness TK2 of the third pattern layer PTL3. In one or more embodiments, the first pattern layer PTL1 may have the thickness TK1 of 700 Å to 1000 Å. According to one or more embodiments, the first pattern layer PTL1 may include a center area CEA defined by the third pattern layer PTL3, which will be described later, and an edge area EGA around (e.g., surrounding) the center area CEA.

According to one or more embodiments, in a plan view, a distance d1 from the side surface of the third pattern layer PTL3 to the side surface of the first pattern layer PTL1 (or the second pattern layer PTL2) may be 2 μm or more.

The second pattern layer PTL2 may be disposed on the first pattern layer PTL1. For example, in order to prevent diffusion (e.g., metal diffusion) between aluminum (e.g., aluminum included in the first pattern layer PTL1) and silver (e.g., silver included in the third pattern layer PTL3 to be described later) in the first electrode AND, the second pattern layer PTL2 may be disposed between the first pattern layer PTL1 and the third pattern layer PTL3. The second pattern layer PTL2 may be in contact with the first pattern layer PTL1 and the third pattern layer PTL3. In one or more embodiments, the overall area of the second pattern layer PTL2 may overlap the overall area of the first pattern layer PTL1. According to one or more embodiments, in a plan view, the area of the second pattern layer PTL2 may be equal to the area of the first pattern layer PTL1. The second pattern layer PTL2 may include a transparent conductive material. For example, the second pattern layer PTL2 may include a transparent conductive material (TCO) such as indium-tin-oxide (ITO) and/or indium-zinc-oxide (IZO). In one or more embodiments, the second pattern layer PTL2 may be formed of a material including ITO. The second pattern layer PTL2 may have a thickness that is less than the third pattern layer PTL3 to be described later. For example, the second pattern layer PTL2 may have a thickness of 100 Å or less.

The third pattern layer PTL3 may be disposed on the second pattern layer PTL2. For example, the third pattern layer PTL3 may be disposed between the second pattern layer PTL2 and the fourth pattern layer PTL4. In one or more embodiments, in a plan view like an example illustrated in FIG. 8, the third pattern layer PTL3 may have a smaller area than the first pattern layer PTL1. In one or more embodiments, the third pattern layer PTL3 may overlap the first pattern layer PTL1. For example, the overall area of the third pattern layer PTL3 may overlap the first pattern layer PTL1. According to one or more embodiments, in a plan view like an example illustrated in in FIG. 8, the third pattern layer PTL3 may be surrounded by the edge of the first pattern layer PTL1. In other words, the third pattern layer PTL3 may be surrounded by an edge area EGA of the first pattern layer PTL1. According to one or more embodiments, the third pattern layer PTL3 may be disposed on the central area CEA of the first pattern layer PTL1. For example, the third pattern layer PTL3 may be disposed between the second pattern layer PTL2 and the fourth pattern layer PTL4 in the central area CEA of the first pattern layer PTL1. The third pattern layer PTL3 may not be disposed on the edge area EGA of the first pattern layer PTL1. The third pattern layer PTL3 may include metal. In one or more embodiments, the third pattern layer PTL3 may include a different metal from the first pattern layer PTL1 described above. For example, the third pattern layer PTL3 may include at least one of silver (Ag) and/or silver alloy. In one or more embodiments, the third pattern layer PTL3 may have a smaller thickness than the first pattern layer PTL1 (TK2<TK1) so that an ultra-fine pattern process (e.g., dry etching process) of the first electrode AND is possible. For example, the third pattern layer PTL3 may have a thickness TK2 that is ¼ the thickness TK1 of the first pattern layer PTL1 or smaller than ¼ the thickness TK1 of the first pattern layer PTL1. In one or more embodiments, the third pattern layer PTL3 may have the thickness of 200 Å to 300 Å.

The fourth pattern layer PTL4 may be disposed on the third pattern layer PTL3. The fourth pattern layer PTL4 may include the same material as the second pattern layer PTL2 described above. For example, the fourth pattern layer PTL4 may include a transparent conductive material (TCO) such as indium-tin-oxide (ITO) and/or indium-zinc-oxide (IZO). In one or more embodiments, the fourth pattern layer PTL4 may be formed of a material containing ITO. The fourth pattern layer PTL4 may have a smaller thickness than the third pattern layer PTL3. For example, the fourth pattern layer PTL4 may have a thickness of 100 Å or less. In one or more embodiments, the thickness of the fourth pattern layer PTL4 may be the same as the thickness of the second pattern layer PTL2 described above. In one or more embodiments, the second pattern layer PTL2 (and/or the fourth pattern layer PTL4) from among the pattern layers PTL1 to PTL4 of the first electrode AND may have the smallest thickness.

The pixel defining film PDL may define emission area of the pixel. For example, the pixel defining film PDL may define a first emission area EA1, a second emission area EA2, and a third emission area EA3. Each of the emission areas EA1 to EA3 may pass through the pixel defining film PDL in the third direction DR3. The pixel defining film PDL may be disposed on the first electrode AND. For example, the pixel defining film PDL may be disposed on the second pattern layer PTL2 to overlap the edge area EGA of the first pattern layer PTL1. In one or more embodiments, at least a portion of the pixel defining film PDL may be disposed between the first electrodes AND adjacent to each other. The pixel defining film PDL of FIG. 9 may include the first pixel defining film PDL1, the second pixel defining film PDL2, and the third pixel defining film PDL3 described above. For the detailed description of the pixel defining film PDL of FIG. 9, refer to the description of the pixel defining film PDL of FIG. 7 described above.

The light emitting stack ES may be disposed on the first electrode AND and the pixel defining film PDL. For example, the light emitting stack ES may be disposed on the second pattern layer PTL2, the fourth pattern layer PTL4, and the pixel defining layer PDL of the first electrode AND. At this time, the light emitting stack ES may be in contact with each of the second pattern layer PTL2, the fourth pattern layer PTL4, and the pixel defining film PDL. The light emitting stack ES may include a plurality of stacks IL1, IL2, and IL3 as described above. For the detailed description of the light emitting stack ES of FIG. 9, refer to the description of the light emitting stack ES of FIG. 7 described above.

The second electrode CAT may be disposed on the light emitting stack ES. For the detailed description of the second electrode CAT of FIG. 9, refer to the description of the second electrode CAT of FIG. 7 described above.

The encapsulation layer TFE may be disposed on the second electrode CAT. For the detailed description of the encapsulation layer TFE of FIG. 9, refer to the description of the encapsulation layer TFE of FIG. 7 described above.

As illustrated in FIG. 7, an optical layer OPL, a cover layer CVL, and a polarizing plate POL may be further disposed on the encapsulation layer TFE.

According to one or more embodiments, the insulating layer INS may correspond to the ninth insulating layer INS9 of FIG. 7. According to one or more other embodiments, the insulating layer INS may correspond to the tenth insulating layer INS10 or eleventh insulating layer INS11 of FIG. 7. In this case, the semiconductor backplane SBP and the light emitting element backplane EBP of FIG. 7 described above may be disposed at the bottom of the insulating layer INS of FIG. 9.

According to one or more embodiments, the first electrode AND may include silver having high reflectivity and aluminum that can be used to produce a fine pattern using dry etching. Accordingly, the first electrode AND of the display device according to one or more embodiments may have high reflectivity even when manufactured in a fine pattern. For example, the first electrode AND including aluminum may be manufactured by dry etching, and thus, the first electrode AND may be formed in a fine pattern. In addition, the first electrode AND including silver may have high reflectivity, and thus, the driving voltage for driving the light emitting stack ES may be reduced to reduce the power consumption. In other words, the efficiency of the display device 10 may be increased. In addition, because the first electrode AND is defined by the first pattern layer PTL1 having a large area, the area of the opening may be increased or maximized. Also, because the second pattern layer PTL2 including ITO is disposed between the first pattern layer PTL1 including aluminum and the third pattern layer PTL3 including silver, metal diffusion between aluminum and silver may be reduced or prevented.

According to one or more embodiments, in a plan view as illustrated in FIG. 8, the edge of the first emission area EA1 may be disposed between the edge of the first pattern layer PTL1 and the edge of the third pattern layer PTL3. The second emission area EA2 and the third emission area EA3 may also have the same arrangement relationship as the first emission area EA1 described above.

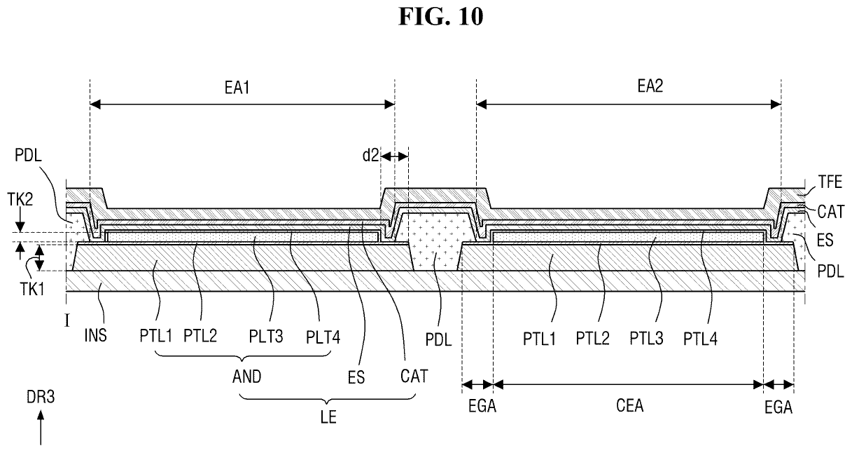

FIG. 10 is a cross-sectional view of a display device according to one or more embodiments. For example, FIG. 10 may be a cross-sectional view taken along the line I-I′ of FIG. 8.

The display device of FIG. 10 is different from the display device of FIG. 9 in the fourth pattern layer PTL4, and the following description will focus on the difference.

As illustrated in FIG. 10, the third pattern layer PTL3 may be surrounded by the second pattern layer PTL2 and the fourth pattern layer PTL4. As an embodiment for this purpose, as illustrated in FIG. 9, the fourth pattern layer PTL4 may be further disposed on the side surface of the third pattern layer PTL3. For example, the fourth pattern layer PTL4 may be disposed on the side surface of the third pattern layer PTL3 and along the side surface thereof.

As illustrated in FIG. 10, because the third pattern layer PTL3 is surrounded by the second pattern layer PTL2 and the fourth pattern layer PTL4, the contact prevention effect between the third pattern layer PTL3 and the first pattern layer PTL1 may be increased, and thus, the metal diffusion issue described above may be more reliably reduced or prevented.

According to one or more embodiments, in a plan view, a distance d2 from the fourth pattern layer PTL4 disposed on the side of the third pattern layer PTL3 to the side of the first pattern layer PTL1 (or the second pattern layer PTL2) may be 2 μm.

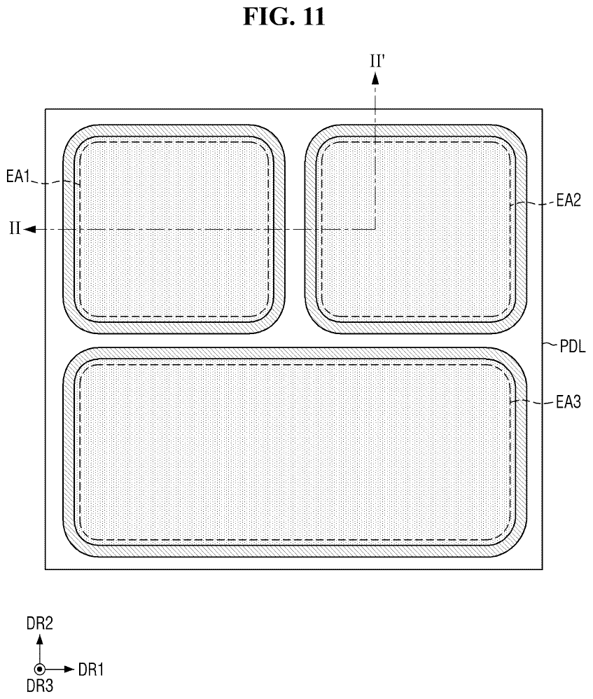

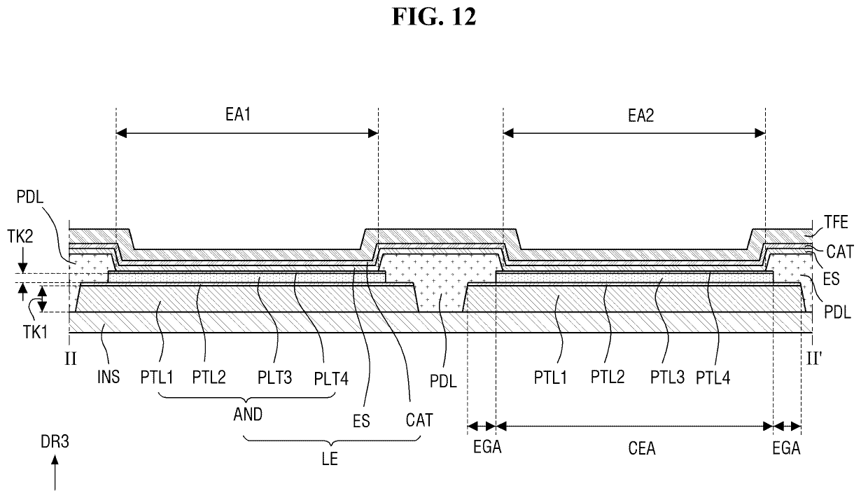

FIG. 11 is a plan view of a display device according to one or more embodiments, and FIG. 12 is a cross-sectional view taken along the line II-II′ of FIG. 11.

The display devices of FIGS. 11 and 12 are different from the display devices of FIGS. 8 and 9 in the pixel defining film PDL, and the following description will focus on the difference.

As illustrated in FIGS. 11 and 12, the pixel defining film PDL may further overlap the third pattern layer PTL3 and the fourth pattern layer PTL4 of the first electrode AND. For example, the pixel defining film PDL may further overlap the edge of the third pattern layer PTL3 and the edge of the fourth pattern layer PTL4. Accordingly, the size of each of the emission areas EA1 to EA3 defined by the pixel defining film PDL may be reduced. However, because the step between the first pattern layer PTL1 and the third pattern layer PTL3 is excluded in the emission area, the image quality in the emission area may be improved.

According to one or more embodiments, in a plan view as illustrated in FIG. 11, the edge of the third pattern layer PTL3 may be disposed between the edge of the first pattern layer PTL1 and the edge of the first emission area EA1. The second emission area EA2 and the third emission area EA3 may also have the same arrangement relationship as the first emission area EA1 described above.

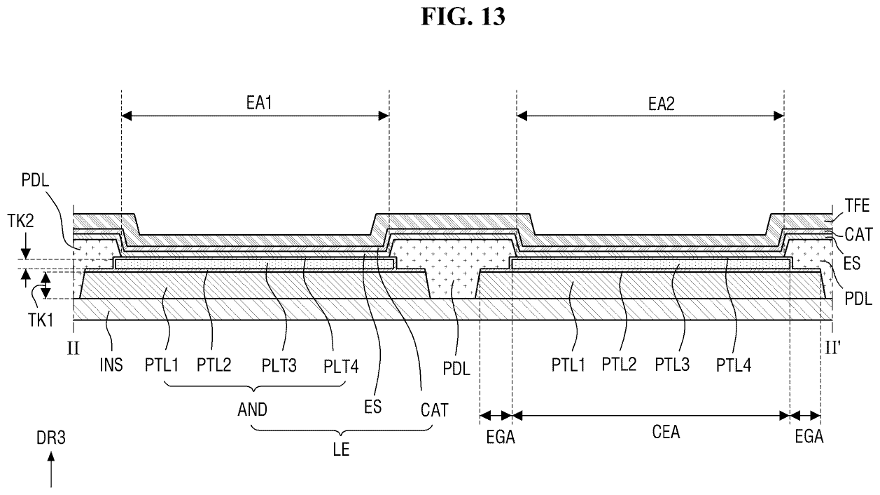

FIG. 13 is a cross-sectional view of a display device according to one or more embodiments. For example, FIG. 13 may be a cross-sectional view taken along the line II-II′ of FIG. 11.

The display device of FIG. 13 is different from the display device of FIG. 12 in the fourth pattern layer PTL4, and the following description will focus on the difference.

As illustrated in FIG. 13, the third pattern layer PTL3 may be surrounded by the second pattern layer PTL2 and the fourth pattern layer PTL4. As an embodiment for this purpose, as illustrated in FIG. 13, the fourth pattern layer PTL4 may be further disposed on the side of the third pattern layer PTL3. For example, the fourth pattern layer PTL4 may be disposed on the side of the third pattern layer PTL3 and along the side thereof.

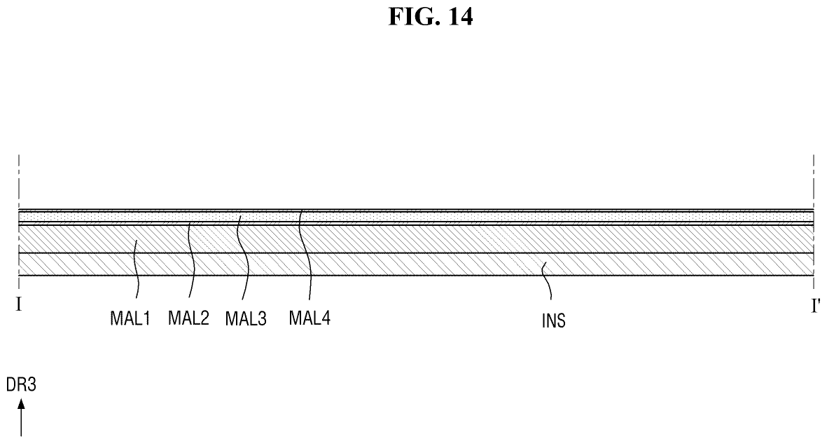

FIGS. 14-20 are cross-sectional views for explaining processes of a method of manufacturing a display device according to one or more embodiments. For example, FIGS. 14-20 may be cross-sectional views for explaining processes of a method of manufacturing a display device illustrated in FIG. 9.

First, as illustrated in FIG. 14, a first material layer MAL1, a second material layer MAL2, a third material layer MAL3, and a fourth material layer MAL4 may be formed sequentially on an insulating layer INS of a substrate. For example, the first material layer MAL1 may be stacked on the insulating layer INS, then the second material layer MAL2 may be stacked on the first material layer MAL1, then the third material layer MAL3 may be stacked on the second material layer MAL2, and then the fourth material layer MAL4 may be stacked on the third material layer MAL3. Here, the first material layer MAL1 may include aluminum, the second material layer MAL2 may include a transparent conductive material, the third material layer MAL3 may include silver, and the fourth material layer MAL4 may include a transparent conductive material.

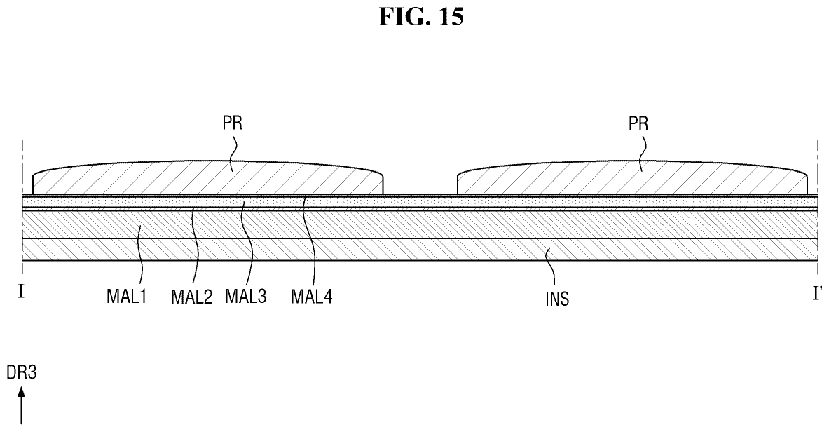

Subsequently, as illustrated in FIG. 15, a photoresist pattern PR may be disposed on the fourth material layer MAL4. When defining a structure including the first material layer MAL1, the second material layer MAL2, the third material layer MAL3, and the fourth material layer MAL4 as a first electrode material layer, the photoresist pattern PR may define a portion corresponding to the first electrode AND from among the first electrode material layer.

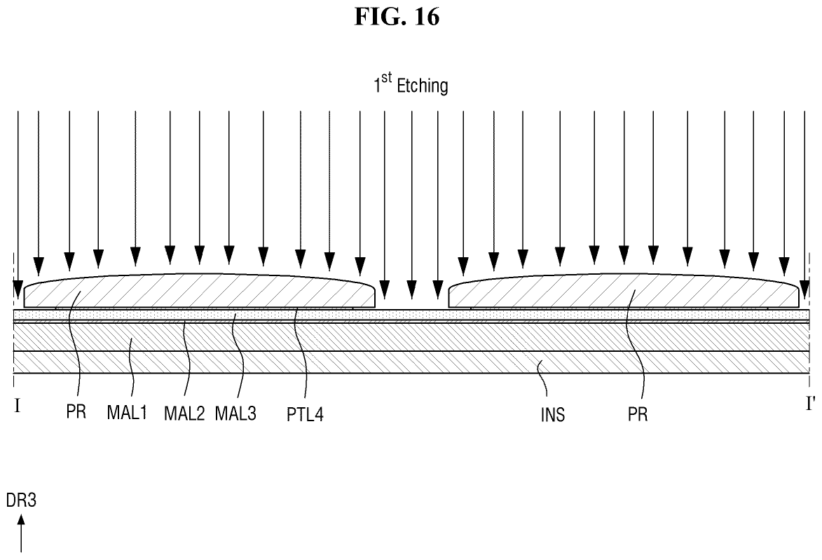

Subsequently, as illustrated in FIG. 16, a first etching process in which the fourth material layer MAL4 is selectively removed using the photoresist pattern PR as a mask may be performed. The first etching process may be proceeded as a wet etching method. At this time, the first etching process may be proceeded as isotropic etching process, and accordingly, not only the exposed portion of the fourth material layer MAL4 that is not covered by the photoresist pattern PR is removed, but also the portion of the fourth material layer MAL4 that overlaps with the edge of the photoresist pattern PR may be partially removed as well. As illustrated in FIG. 16, as the fourth material layer MAL4 is selectively etched using the photoresist pattern PR as a mask, a fourth pattern layer PTL4 may be formed.

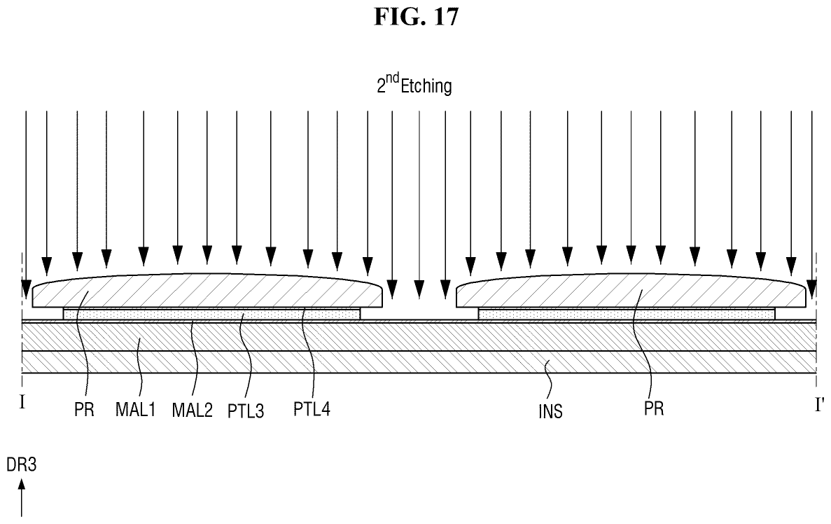

Next, as illustrated in FIG. 17, a second etching process in which the third material layer MAL3 is selectively removed using the photoresist pattern PR described above as a mask may be performed. The second etching process may be proceeded as wet etching method. At this time, the second etching process may be proceeded as isotropic etching process, and accordingly, not only the exposed portion of the third material layer MAL3 that is not covered by the photoresist pattern PR is removed, but also the portion of the third material layer MAL3 that overlaps with the edge of the photoresist pattern PR may be partially removed as well. As illustrated in FIG. 17, as the third material layer MAL3 is selectively removed using the photoresist pattern PR as a mask, a third pattern layer PTL3 may be formed.

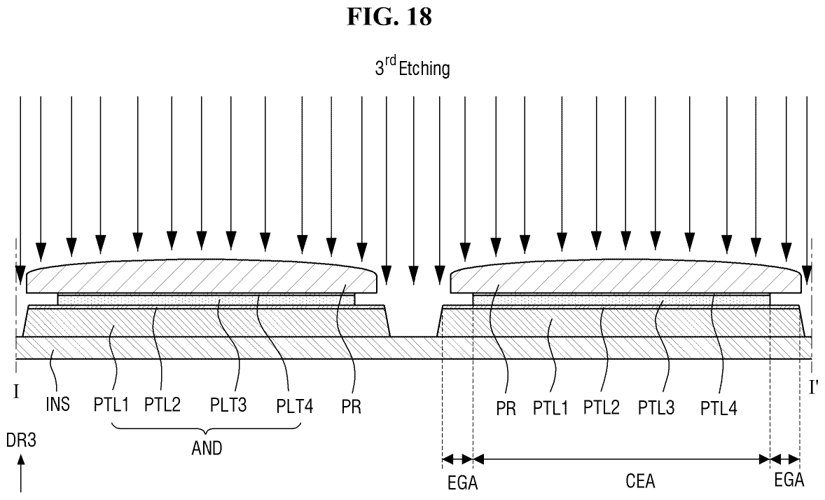

Next, as illustrated in FIG. 18, a third etching process in which each of the second material layer MAL2 and the first material layer MAL1 are selectively removed using the photoresist pattern PR described above as a mask may be performed. The third etching process may be proceeded as dry etching method. At this time, the third etching process may be proceeded as isotropic etching process, and accordingly, the exposed portion of the second material layer MAL2 that is not covered by the photoresist pattern PR and the exposed portion of the first material layer MAL1 that is not covered by the photoresist pattern PR are selectively removed. Because the thickness of the second material layer MAL2 is significantly small, the second material layer MAL2 may be removed together with the first material layer MAL1 during the third etching process (e.g., dry etching process). As illustrated in FIG. 18, as the second material layer MAL2 and the first material layer MAL1 are selectively etched using the photoresist pattern PR as a mask, a second pattern layer PTL2 and a first pattern layer PTL1 may be formed. As a result, when the third etching process as illustrated in FIG. 18 is performed and completed, a first electrode AND including the first pattern layer PTL1, the second pattern layer PTL2, the third pattern layer PTL3, and the fourth pattern layer PTL4 may be formed. For example, the first electrode AND may be disposed between the insulating layer INS and the photoresist pattern PR.

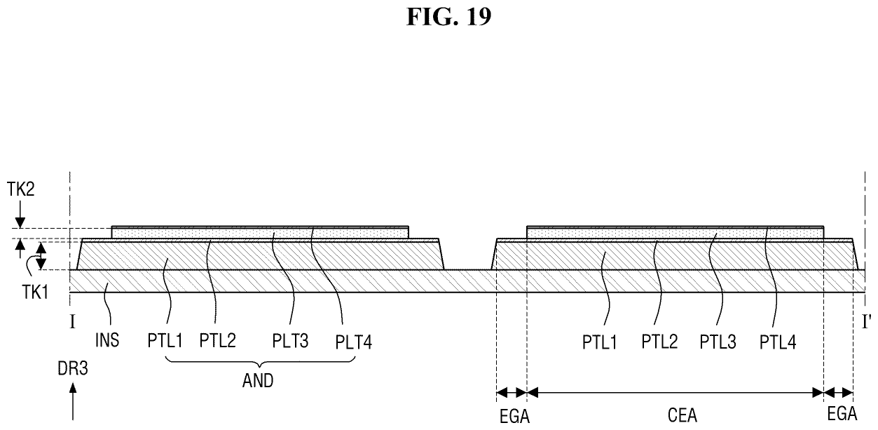

Thereafter, as illustrated in FIG. 19, the photoresist pattern PR on the first electrode AND may be removed. For example, the photoresist pattern PR may be removed by the strip process.

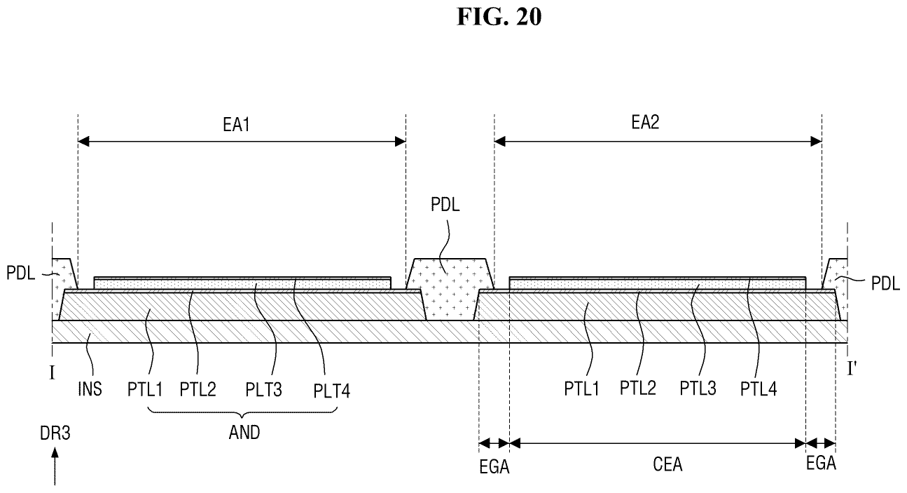

Next, as illustrated in FIG. 20, a pixel defining film PDL defining emission areas EA1 to EA3 may be disposed on the first electrode AND. For example, the pixel defining film PDL may be disposed on the edge of the second pattern layer PTL2 to overlap an edge area EGA of the first pattern layer PTL1.

Subsequently, as illustrated in FIG. 7, a light emitting stack ES is formed on the first electrode AND and the pixel defining film PDL, then a second electrode CAT is formed on the light emitting stack ES, then an encapsulation layer TFE is formed on the second electrode CAT.

In addition, as illustrated in FIG. 7, an organic film APL, an optical layer OPL, a cover layer CVL, and a polarizing plate POL may be sequentially formed on the encapsulation layer TFE.

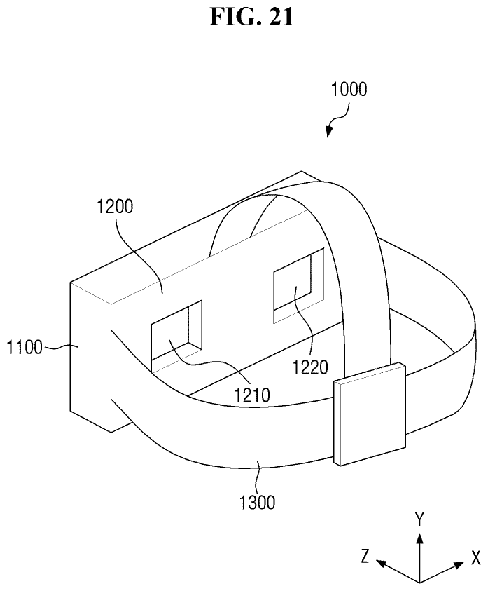

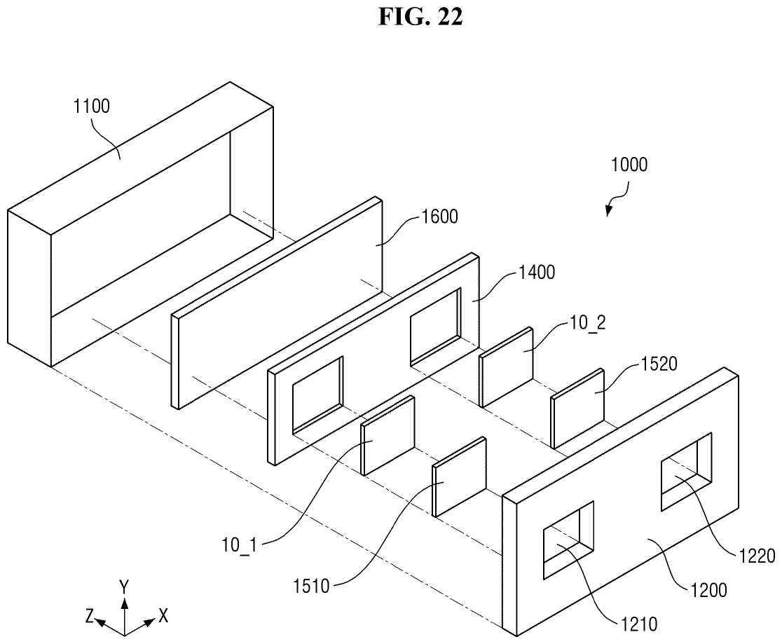

FIG. 21 is a perspective view illustrating a head mounted display device according to one or more embodiments. FIG. 22 is an exploded perspective view illustrating an example of the head mounted display device of FIG. 21.

Referring to FIGS. 21 and 22, a head mounted display device 1000 according to one or more embodiments includes a first display device 10_1, a second display device 10_2, a display device housing part 1100, a housing part cover 1200, a first eyepiece 1210, a second eyepiece 1220, a head mounted band 1300, a middle frame 1400, a first optical member 1510, a second optical member 1520, and a control circuit board 1600.

The first display device 101 provides an image to a user's left eye, and the second display device 10_2 provides an image to a user's right eye. Each of the first display device 10_1 and the second display device 10_2 is substantially the same as the display device 10 described with reference to FIGS. 1 and 2, and a description of the first display device 10_1 and the second display device 10_2 is thus omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and be disposed between the second display device 10_2 and the control circuit board 1600. The middle frame 1400 serves to support and fix the first display device 10_1, the second display device 102, and the control circuit board 1600.

The control circuit board 1600 may be disposed between the middle frame 1400 and the display device housing part 1100. The control circuit board 1600 may be connected to the first display device 10_1 and the second display device 10_2 through a connector. The control circuit board 1600 may convert an image source input from the outside into digital video data DATA, and transmit the digital video data DATA to the first display device 10_1 and the second display device 10_2 through the connector.

The control circuit board 1600 may transmit digital video data DATA corresponding to a left eye image optimized for the user's left eye to the first display device 10_1 and transmit digital video data DATA corresponding to a right eye image optimized for the user's right eye to the second display device 10_2. Alternatively, the control circuit board 1600 may transmit the same digital video data DATA to the first display device 10_1 and the second display device 10_2.

The display device housing part 1100 serves to house the first display device 10_1, the second display device 10_2, the middle frame 1400, the first optical member 1510, the second optical member 1520, and the control circuit board 1600. The housing part cover 1200 is disposed to cover opened one surface of the display device housing part 1100. The housing part cover 1200 may include the first eyepiece 1210 on which the user's left eye is disposed and the second eyepiece 1220 on which the user's right eye is disposed. It has been illustrated in FIGS. 21 and 22 that the first eyepiece 1210 and the second eyepiece 1220 are separately disposed, but the present disclosure is not limited thereto. The first eyepiece 1210 and the second eyepiece 1220 may be merged as one eyepiece.

The first eyepiece 1210 may be aligned with the first display device 10_1 and the first optical member 1510, and the second eyepiece 1220 may be aligned with the second display device 10_2 and the second optical member 1520. Accordingly, a user may view an image of the first display device 10_1 magnified as a virtual image by the first optical member 1510 through the first eyepiece 1210, and may view an image of the second display device 102 magnified as a virtual image by the second optical member 1520 through the second eyepiece 1220.

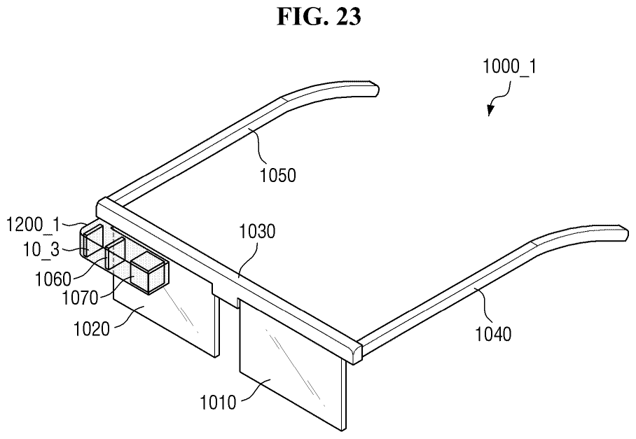

The head mounted band 1300 serves to fix the display device housing part 1100 to a user's head so that the first eyepiece 1210 and the second eyepiece 1220 of the housing part cover 1200 may be maintained in a state in which they are disposed on the user's left eye and right eye, respectively. When the display device housing part 1200 is implemented to have a light weight and a small size, the head mounted display device 1000 may include an eyeglass frame as illustrated in FIG. 23 instead of the head mounted band 1300.

In addition, the head mounted display device 1000 may further include a battery for supplying power, an external memory slot for housing an external memory, and an external connection port and a wireless communication module for receiving an image source. The external connection port may be a universe serial bus (USB) terminal, a display port, and/or a high-definition multimedia interface (HDMI) terminal, and the wireless communication module may be a 5G communication module, a 4G communication module, a wireless fidelity (WiFi) module, and/or a Bluetooth module.

FIG. 23 is a perspective view illustrating a head mounted display device according to one or more embodiments.

Referring to FIG. 23, a head mounted display device 1000_1 according to one or more embodiments may be a glasses-type display device in which a display device housing part 1200_1 is implemented to have a light weight and a small size. The head mounted display device 1000_1 according to one or more embodiments may include a display device 10_3, a left eye lens 1010, a right eye lens 1020, a support frame 1030, glasses frame legs 1040 and 1050, an optical member 1060, an optical path conversion member 1070, and a display device housing part 1200_1.

The display device housing part 1200_1 may include the display device 10_3, the optical member 1060, and the optical path conversion member 1070. An image displayed on the display device 103 may be magnified by the optical member 1060, converted in an optical path by the optical path conversion member 1070, and provided to a user's right eye through the right eye lens 1020. For this reason, a user may view an augmented reality image in which a virtual image displayed on the display device 10_3 through his/her right eye and a real image seen through the right eye lens 1020 are combined with each other.

It has been illustrated in FIG. 23 that the display device housing part 12001 is disposed at a right end of the support frame 1030, but the present disclosure is not limited thereto. For example, the display device housing part 12001 may be disposed at a left end of the support frame 1030, and in this case, an image of the display device 10_3 may be provided to a user's left eye. Alternatively, the display device housing parts 1200_1 may be disposed at both the left and right ends of the support frame 1030, and in this case, the user may view an image displayed on the display device 10_3 through both his/her left and right eyes.

In concluding the detailed description, those skilled in the art will appreciate that many variations and modifications can be made to the embodiments without substantially departing from the principles or scope of the present disclosure. Therefore, the embodiments of the present disclosure are used in a generic and descriptive sense only and not for purposes of limitation.

What is claimed is:

1. A display device comprising:
a substrate;
a first electrode on the substrate;
a light emitting layer on the first electrode; and
a second electrode on the light emitting layer,
wherein the first electrode comprises:
a first pattern layer comprising aluminum;
a second pattern layer on the first pattern layer and comprising a transparent conductive material;
a third pattern layer on the second pattern layer and comprising silver; and
a fourth pattern layer on the third pattern layer and comprising a transparent conductive material.

2. The display device of claim 1, wherein the first pattern layer has a greater thickness than the thickness of the third pattern layer.

3. The display device of claim 2, wherein the thickness of the first pattern layer is four times the thickness of the third pattern layer.

4. The display device of claim 1, wherein the first pattern layer has a thickness in a range of 700 Å to 1000 Å.

5. The display device of claim 1, wherein the third pattern layer has a thickness in a range 200 Å to 300 Å.

6. The display device of claim 1, wherein the second pattern layer has a thickness equal to or less than 100 Å.

7. The display device of claim 1, wherein the fourth pattern layer has a thickness equal to or less than 100 Å.

8. The display device of claim 1, wherein, in a plan view, the first pattern layer has a greater area than the third pattern layer.

9. The display device of claim 1, wherein, in a plan view, the first pattern layer has a greater area than the second pattern layer or the fourth pattern layer.

10. The display device of claim 1,
wherein the third pattern layer is surrounded by the second pattern layer and the fourth pattern layer.

11. The display device of claim 1, further comprising a pixel defining film on the first electrode.

12. The display device of claim 11, wherein the pixel defining film is on the second pattern layer and overlaps an edge area of the first pattern layer.

13. The display device of claim 11,
wherein the pixel defining film is on the second pattern layer and the fourth pattern layer and overlaps the edge area of the first pattern layer.

14. The display device of claim 1,
wherein the transparent conductive material comprises ITO.

15. An optical device comprising:
a display device; and
an optical path conversion member on the display device,
wherein the display device comprises:
a substrate;
a first electrode on the substrate;
a light emitting layer on the first electrode; and
a second electrode on the light emitting layer,
wherein the first electrode comprises:
a first pattern layer comprising aluminum;
a second pattern layer on the first pattern layer and comprising a transparent conductive material;
a third pattern layer on the second pattern layer and comprising silver; and
a fourth pattern layer on the third pattern layer and comprising a transparent conductive material.

16. The optical device of claim 15, wherein the first pattern layer has a greater thickness than the third pattern layer.

17. The optical device of claim 15, wherein, in a plan view, the first pattern layer has a greater area than the third pattern layer.

18. The optical device of claim 15, wherein, in a plan view, the first pattern layer has a greater area than the second pattern layer or the fourth pattern layer.

19. A method of manufacturing a display device,
the method comprising forming a first electrode on a substrate,
wherein forming the first electrode comprises:
sequentially forming a first material layer comprising aluminum, a second material layer comprising a transparent conductive material, a third material layer comprising silver, and a fourth material layer comprising a transparent conductive material;
forming a photoresist pattern on the fourth material layer;
forming a fourth pattern layer by wet etching the fourth material layer using the photoresist pattern as a mask;
forming a third pattern layer by wet etching the third material layer using the photoresist pattern as a mask; and
forming each of the second pattern layer and the first pattern layer by respectively dry etching the second material layer and the first material layer using the photoresist pattern as a mask.

20. The method of claim 19, further comprising:
forming a pixel defining film on a first electrode comprising the first pattern layer, the second pattern layer, the third pattern layer, and the fourth pattern layer;
forming a light emitting layer on the first electrode and the pixel defining film; and
forming a second electrode on the light emitting layer.
